(19) United States
(12) Patent Application Publication
(10) Pub. No.: US 2025/0192113 A1
(43) Pub. Date: Jun. 12, 2025

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Yoshiyuki KUROKAWA, Sagamihara, Kanagawa (JP); Hiromichi GODO, Isehara, Kanagawa (JP)

(21) Appl. No.: 18/845,975

(22) PCT Filed: Apr. 11, 2023
(86) PCT No.: PCT/IB2023/053650

§ 371 Date: Sep. 11, 2024

(30) Foreign Application Priority Data
Apr. 22, 2022 (JP) 2022-070482

(51) Int. Cl. H01L 25/07; H10B 10/00; H10B 80/00

(52) U.S. Cl. CPC H01L 25/074; H10B 10/12; H10B 80/00; H01L 2225/06541

(57) ABSTRACT

A semiconductor device with a novel structure is provided. The semiconductor device includes a first element layer including a control portion and a second element layer stacked and provided over the first element layer. The second element layer includes a memory portion that functions as a set associative type cache memory including n ways (n is greater than or equal to 2) and an input/output portion that has a function of inputting/outputting data stored in the memory portion. In the second element layer, n element layers are stacked and provided. The n element layers each include a first transistor. In the first transistor, a semiconductor layer including a channel formation region includes silicon. The n element layers each include the memory portion and the input/output portion that are separately provided. The memory portion provided in any one of the n element layers outputs data corresponding to any one of the n ways to the control portion through the input/output portion provided in any one of the n element layers.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device, a driving method thereof, and a manufacturing method thereof.

### BACKGROUND ART

Many central processing units (CPUs) are mounted with cache memories that temporarily store data. A cache memory is a memory capable of high-speed operation that copies and stores part of the content of data in a low-speed main memory. When data required by a CPU is stored in a cache memory, the CPU can execute arithmetic processing at high speed.

Typical cache memory structures are a fully associative type, a direct map type, a set associative type, and the like (for example, see Patent Document 1).

A set associative type (n way-set associative type) cache memory including n ways includes a plurality of memory sets in each way. The memory set stores identification information such as a flag or a tag as well as data. In the case where desired data is read, an address signal (an address) including identification information such as a tag, a set, and an offset is input to each way. The desired data can be selected by, for example, comparison of the input address with the tag stored in the memory set and can be output as the data of the memory set.

In addition, in recent years, research and development of a structure where dies each provided with an SRAM cell (for example, Si dies) are three-dimensionally stacked and provided to increase the memory capacity of a cache memory have been actively conducted (for example, Non-Patent Document 1 and Non-Patent Document 2).

### REFERENCES

### Patent Document

[Patent Document 1] PCT International Publication No. 2011/049051

### Non-Patent Documents

[Non-Patent Document 1]T. Burd et al., ISSCC Dig. Tech. Papers, pp. 54-55, 2022.
[Non-Patent Document 2]J. Wuu et al., ISSCC Dig. Tech. Papers, pp. 428-429, 2022.

### SUMMARY OF THE INVENTION

### Problems to be Solved by the Invention

In the case where element layers in each of which a memory cell that functions as a cache memory is provided, for example, Si dies each provided with an SRAM cell are three-dimensionally stacked, the Si dies are electrically connected with a technique using through electrodes such as TSVs (Through Silicon Vias), a Cu—Cu (copper-copper) direct bonding technique (a technique establishing electrical conduction by connecting Cu (copper) pads to each other), or the like. In that case, a resistance component due to bonding between the Si die and the Si die is generated. As the number of stacked Si dies increases, a resistance component between a Si die in a lower layer and a Si die in an upper layer increases.

The increase in the resistance component between the Si die in the lower layer and the Si die in the upper layer might cause a variation in signal delay. For example, in the case where Si dies each function as a cache memory are three-dimensionally stacked and an address signal is input to read desired data, comparison of operation of accessing only to the Si die in the lower layer and operation of accessing only to the Si die in the upper layer might cause a variation in signal delay.

One object of one embodiment of the present invention is to provide a semiconductor device with a novel structure that can reduce a variation in signal delay in a structure including a cache memory where a plurality of element layers are stacked and provided. Another object of one embodiment of the present invention is to provide a semiconductor device with a novel structure that is excellent in computing efficiency. Another object of one embodiment of the present invention is to provide a semiconductor device that is excellent in reducing power consumption. Another object of one embodiment of the present invention is to provide a semiconductor device with a novel structure.

Note that the objects of one embodiment of the present invention are not limited to the objects listed above. The objects listed above do not preclude the presence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device that includes a first element layer including a control portion and a second element layer stacked and provided over the first element layer. The second element layer includes a memory portion that functions as a set associative type cache memory including n ways (n is greater than or equal to 2) and an input/output portion that has a function of inputting/outputting data stored in the memory portion. In the second element layer, n element layers are stacked and provided. The n element layers each include a first transistor. In the first transistor, a semiconductor layer including a channel formation region includes silicon. The n element layers each include the memory portion and the input/output portion that are separately provided. The memory portion provided in any one of the n element layers outputs data corresponding to any one of the n ways to the control portion through the input/output portion provided in any one of the n element layers.

In the semiconductor device according to one embodiment of the present invention, it is preferable that a memory cell included in the memory portion be an SRAM cell.

In the semiconductor device according to one embodiment of the present invention, it is preferable that the n element layers each include a through electrode provided to penetrate a substrate including the first transistor and that the through electrodes provided in different element layers be electrically connected through a metal bump provided between the element layers.

In the semiconductor device according to one embodiment of the present invention, it is preferable that the first element layer include an arithmetic portion and that the second element layer be provided in a region not overlapping a region where the arithmetic portion is provided.

In the semiconductor device according to one embodiment of the present invention, it is preferable that the input/output portions included in the n element layers include a region where the input/output portions included in the n element layers overlap each other.

One embodiment of the present invention is a semiconductor device that includes a first element layer including a control portion and a second element layer stacked and provided over the first element layer. The second element layer includes a memory portion that functions as a set associative type cache memory including n ways (n is greater than or equal to 2) and an input/output portion that has a function of inputting/outputting data stored in the memory portion. In the second element layer, n element layers are stacked and provided. The n element layers each include a first transistor. In the first transistor, a semiconductor layer including a channel formation region includes an oxide semiconductor. The n element layers each include the memory portion and the input/output portion that are separately provided. The memory portion provided in any one of the n element layers outputs data corresponding to any one of the n ways to the control portion through the input/output portion provided in any one of the n element layers.

In the semiconductor device according to one embodiment of the present invention, it is preferable that a memory cell included in the memory portion be a memory cell including the first transistor.

In the semiconductor device according to one embodiment of the present invention, it is preferable that the n element layers be provided by superimposing a plurality of layers each including the first transistor and that the n element layers be electrically connected through a wiring layer provided in the layer including the first transistor.

In the semiconductor device according to one embodiment of the present invention, it is preferable that the first element layer include an arithmetic portion and that the second element layer be provided in a region not overlapping a region where the arithmetic portion is provided.

In the semiconductor device according to one embodiment of the present invention, it is preferable that the input/output portions included in the n element layers include a region where the input/output portions included in the n element layers overlap each other.

In one embodiment of the present invention, the oxide semiconductor preferably includes In, Ga, and Zn.

Note that other embodiments of the present invention are illustrated in the description of the following embodiments and the drawings.

### Effect of the Invention

One embodiment of the present invention can provide a semiconductor device with a novel structure that can reduce a variation in signal delay in a structure including a cache memory where a plurality of element layers are stacked and provided. Alternatively, one embodiment of the present invention can provide a semiconductor device with a novel structure that is excellent in computing efficiency. Alternatively, one embodiment of the present invention can provide a semiconductor device that is excellent in reducing power consumption. Alternatively, one embodiment of the present invention can provide a semiconductor device with a novel structure.

Note that the description of these effects does not preclude the presence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are diagrams each illustrating a structure example of a semiconductor device.

FIG. 2A and FIG. 2B are diagrams each illustrating a structure example of the semiconductor device.

FIG. 3 is a diagram illustrating a structure example of the semiconductor device.

FIG. 4A and FIG. 4B are diagrams each illustrating a structure example of the semiconductor device.

FIG. 5 is a diagram illustrating a structure example of the semiconductor device.

FIG. 6 is a diagram illustrating a structure example of a semiconductor device.

FIG. 7A and FIG. 7B are diagrams each illustrating a structure example of the semiconductor device.

FIG. 8A to FIG. 8D are diagrams each illustrating a structure example of a semiconductor device.

FIG. 9A to FIG. 9C are diagrams each illustrating a structure example of a semiconductor device.

FIG. 10A and FIG. 10B are diagrams each illustrating a structure example of a semiconductor device.

FIG. 11 is a diagram illustrating a structure example of a semiconductor device.

FIG. 12A to FIG. 12C are diagrams illustrating structure examples of semiconductor devices.

FIG. 13 is a diagram illustrating a structure example of a memory portion.

FIG. 14A is a diagram illustrating a structure example of a memory layer. FIG. 14B is a diagram illustrating an equivalent circuit of the memory layer.

FIG. 15 is a diagram illustrating a structure example of the memory portion.

FIG. 16A is a diagram illustrating a structure example of memory layers. FIG. 16B is a diagram illustrating an equivalent circuit of the memory layers.

FIG. 17A and FIG. 17B are diagrams each illustrating an example of an electronic component.

FIG. 18A and FIG. 18B are diagrams each illustrating an example of an electronic device, and

FIG. 18C to FIG. 18E are diagrams each illustrating an example of a large computer.

FIG. 19 is a diagram illustrating an example of space equipment.

FIG. 20 illustrates an example of a storage system applicable to a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In addition, in the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an off state (also referred to as a non-conduction state or a cutoff state). Unless otherwise specified, an off state in an n-channel transistor refers to a state where voltage V_{gs} between its gate and source is lower than threshold voltage Vth (in a p-channel transistor, higher than Vth).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, in the case where an OS transistor is stated, the OS transistor can also be referred to as a transistor including a metal oxide or an oxide semiconductor.

### Embodiment 1

In this embodiment, structure examples of semiconductor devices will be described. Semiconductor devices described in one embodiment of the present invention each have a function of a processor including a cache memory, such as a CPU.

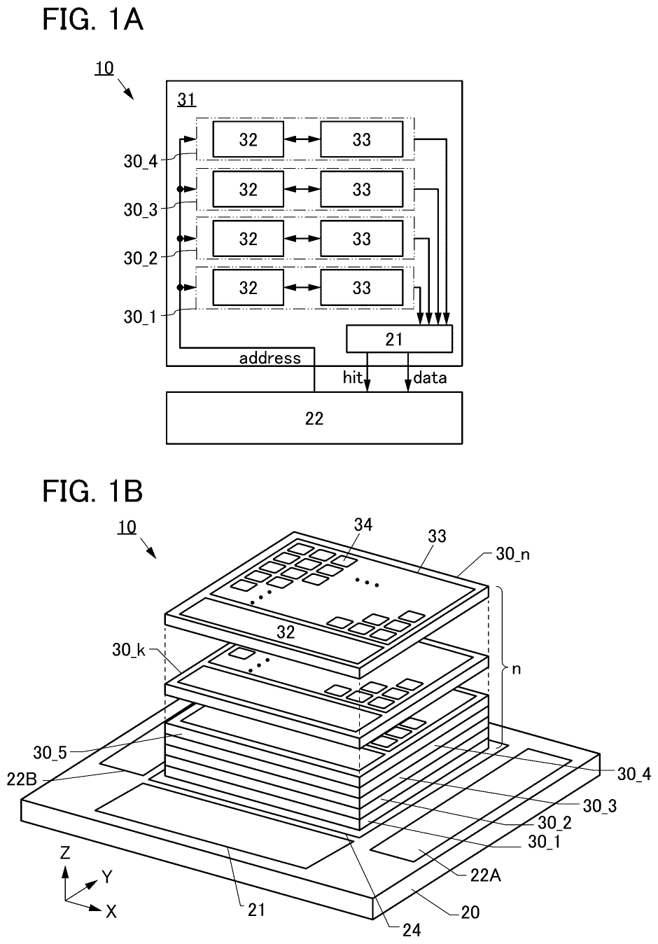

FIG. 1A is a block diagram for illustrating the semiconductor device according to one embodiment of the present invention. FIG. 1B is a schematic perspective view for illustrating the semiconductor device according to one embodiment of the present invention.

A semiconductor device 10 illustrated in FIG. 1A includes a cache memory 31 and an arithmetic portion 22. The cache memory 31 includes a plurality of element layers 30 and a control portion 21. In FIG. 1A, element layers 30_1 to 30_4 are illustrated as an example of the plurality of element layers 30.

The cache memory 31 is a circuit used to store data temporarily when the arithmetic portion 22 performs arithmetic processing. The cache memory 31 is a circuit having a function of temporarily storing data on a signal or the like corresponding to a calculation result obtained by arithmetic processing of the arithmetic portion 22 to increase data processing speed.

The arithmetic portion 22 is a circuit that performs arithmetic processing such as logical operation or address operation in accordance with an input signal or data. The arithmetic portion 22 is sometimes referred to as a signal processing circuit or a CPU core. An example of a signal input to the arithmetic portion 22 is a clock signal. An example of data input to the arithmetic portion 22 is data input from the cache memory 31. The arithmetic portion 22 outputs an address signal (in the drawing, represented as “address”) to the cache memory 31 so that it can acquire data from the cache memory 31. A hit signal (in the drawing, represented as “hit”) is input from the control portion 21 to the arithmetic portion 22. In the case of a cash hit, data (in the drawing, represented as “data”) is input by the hit signal. In the case of a cash miss, the arithmetic portion 22 requests data to a main memory (not illustrated) such as a DRAM.

The semiconductor device 10 illustrated in FIG. 1B illustrates an appearance where n element layers 30 (n is an integer greater than or equal to 2) are stacked and provided over an element layer 20. When the n element layers 30 are provided over the element layer 20, the area occupied by the cache memory can be reduced. Furthermore, memory capacity per unit area can be increased. Note that the element layer 20 is sometimes referred to as a first element layer, and the element layer 30 is sometimes referred to as a second element layer.

As the element layers 30, a plurality of element layers can be superimposed and provided by three-dimensionally stacking dies (Si dies) each provided with an SRAM cell. The SRAM cell is preferable because operation can be performed at higher speed than a DRAM or the like. The element layer 30 includes a transistor that includes silicon in a semiconductor layer including a channel formation region (a Si transistor). Including the Si transistor enables a structure where input/output portion 32 and memory portion 33 are formed using a CMOS circuit (a Si CMOS circuit). With this structure, a memory cell and an input/output circuit of the Si CMOS circuit can be placed in each layer. The input/output portion 32 and the memory portion 33 can be formed using a CMOS circuit and thus can operate at high speed.

Note that for the semiconductor layer including the channel formation region in the Si transistor, a single crystal semiconductor, a polycrystalline semiconductor, a microcrystalline semiconductor, an amorphous semiconductor, or the like can be used alone or in combination. A semiconductor material is not limited to silicon, and germanium or the like can be used, for example. Alternatively, a compound semiconductor such as silicon germanium, silicon carbide, gallium arsenide, or a nitride semiconductor may be used.

In FIG. 1, a first element layer 30 is denoted by an element layer 301, a second element layer 30 is denoted by an element layer 302, and a third element layer 30 is denoted by an element layer 30_3. Furthermore, a k-th element layer 30 (k is an integer greater than or equal to 1 and less than or equal to n) is denoted by an element layer 30_k, and an n-th element layer 30 is denoted by an element layer 30_n. Note that in this embodiment and the like, the “element layer 30” is merely stated in some cases when describing a matter related to all the n element layers 30 or showing a matter common to the n element layers 30.

Note that in the description in this specification, a row direction and a column direction where memory cells 34 are provided are an X direction and a Y direction, respectively, and a direction perpendicular to a surface of the element layer 20 or a direction where the n element layers 30 are stacked and provided is a Z direction.

The element layers 30 in which the dies each including the Si transistor are stacked and provided can be stacked element layers by connecting substrates with a technique using through electrodes such as TSVs (Through Silicon Vias), a Cu—Cu (copper-copper) direct bonding technique (a technique establishing electrical conduction by connecting Cu (copper) pads to each other), or the like.

The memory portion 33 includes a plurality of memory cells 34. An SRAM cell can be employed as each memory cell 34. A memory set including cache data is stored in the set associative type (n way-set associative type) memory portion 33 including n (n is greater than or equal to 2) ways. The memory portion 33 functions as an n way-set associative type cache memory. The memory set stores identification information such as a flag or a tag as well as data. In the case where desired data is read, an address signal including identification information such as a tag, a set, and an offset is input to each way. Note that the way is sometimes referred to as a dataset.

The input/output portion 32 includes a circuit for selecting desired data by, for example, comparison of an input address with the tag stored in the memory set and outputting the desired data to the control portion 21 as data of the memory set. In addition, the input/output portion 32 includes a circuit such as a sense amplifier for reading data stored in the memory cell 34 in the memory portion 33. The input/output portion 32 has a function of inputting/outputting data stored in the memory portion 33.

With a structure where the input/output portion 32 is provided in each of the element layers 30, the input/output portions 32 can be placed to overlap each other. With such a structure, the semiconductor device can be downsized. In addition, when each layer includes a circuit for processing a signal such as an address signal, the number of signals between each of the element layers 30 and the control portion 21 can be reduced.

The input/output portions 32 and the memory portions 33 are provided across the plurality of element layers 30. Each of the plurality of element layers 30 can be referred to as the input/output portion 32 and the memory portion 33 that are separately provided.

Furthermore, in the semiconductor device 10 illustrated in FIG. 1B, the element layer 20 that is provided to overlap the element layer 30 is provided with, for example, arithmetic portions 22A and 22B, a memory portion 24, and the control portion 21.

The element layer 20 can employ a structure where a CMOS circuit is formed using a Si transistor including silicon in a semiconductor layer including a channel formation region and the arithmetic portions 22A and 22B, the memory portion 24, and the control portion 21 are formed. Since the arithmetic portions 22A and 22B, the memory portion 24, and the control portion 21 can be formed using a CMOS circuit, the arithmetic portions 22A and 22B, the memory portion 24, and the control portion 21 can operate at high speed.

The control portion 21 includes a circuit that outputs a hit signal and the like based on a signal obtained by comparison or the like of the input address and the tag stored in the memory set as the data of the memory set, and a circuit for outputting data selected based on the hit signal to the arithmetic portions 22 (22A and 22B).

With respect to the arithmetic portions 22 (22A and 22B), in the case where the semiconductor device 10 that functions as a CPU is a single-core CPU, there is one arithmetic portion in the semiconductor device 10. In the case where the semiconductor device 10 that functions as a CPU is a multi-core CPU, there are a plurality of arithmetic portions in the semiconductor device 10. In the semiconductor device 10 illustrated in FIG. 1B, the two arithmetic portions 22A and 22B are illustrated as an example.

The memory portion 24 functions as a cache memory placed in a position close to the arithmetic portions 22. For example, in the case where a primary cache is provided in each of the arithmetic portions 22A and 22B, the memory portion 24 can be used as a secondary cache. In addition, in that case, the memory portion 33 provided in the element layer 30 can be used as a third-level cache.

The element layer 30 provided over the element layer 20 is preferably provided in a region that does not overlap regions where the arithmetic portions 22A and 22B are provided. For example, the element layer 30 provided over the element layer 20 is preferably provided in a region that overlaps a region where the memory portion 24 is provided.

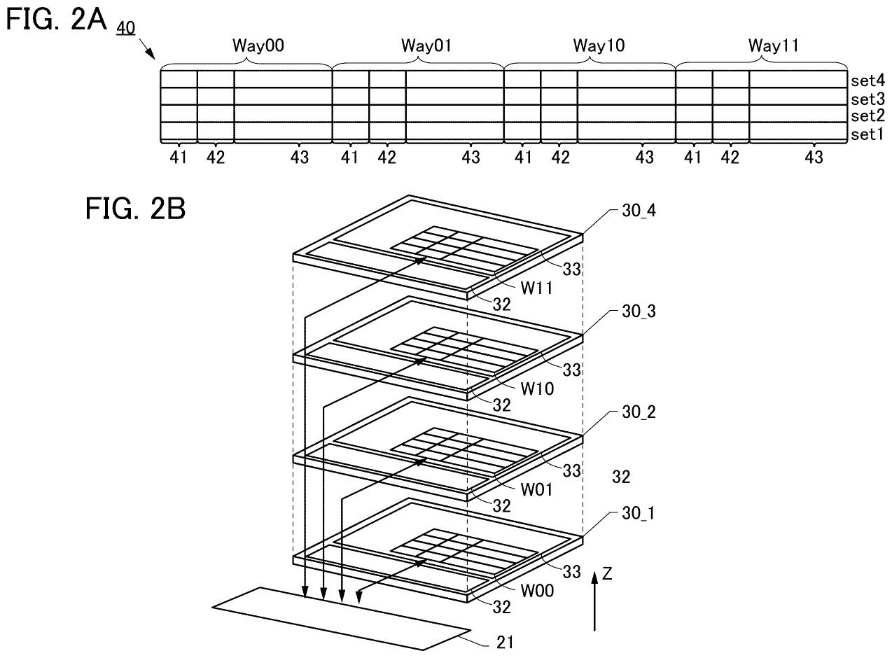

FIG. 2A is a schematic diagram of a data field 40 of data stored in the memory portion 33 provided in the element layer 30. FIG. 2A illustrates four ways, that is, a 4 way-set associative type data field as an example. The four ways are denoted by Way00, Way01, Way10, and Way 11, and identification information of a flag 41, a tag 42, and data 43 is included in each way. A plurality of sets are included in each way, and sets set1 to set4 are illustrated as an example. Note that the set is sometimes referred to as a data line.

In the case where an address signal is input to a plurality of ways each of which is a group of data corresponding to a symbol (an index) assigned using part of an address, a set corresponding to the address signal is selected from sets of a plurality of data. That is, identification information of any one of a plurality of sets is selected from each way by the address signal. Whether identification information of the selected set is a cache hit or a cache miss is determined by comparison of tags. In the case of the cache hit, data corresponding to the tag is read.

Note that although FIG. 2A illustrates the data field including the four ways, the data field may include two ways or eight ways. In addition, in the case where the memory portion 33 included in the element layer 30 is used as a secondary cache or a third-level cache, the data field can also include 16 ways, 24 ways, or more ways.

FIG. 2B is a schematic diagram for illustrating the memory portion 33 of the element layer 30 that stores data corresponding to each way. A block WOO corresponding to Way00 illustrated in FIG. 2A, a block W01 corresponding to Way01, a block W10 corresponding to Way10, and a block W11 corresponding to Way11 are separately stored in the memory portions 33 of the respective element layers 30_1 to 30_4 that are stacked across the Z direction. That is, the memory portion 33 provided in any one of the element layers 30 stores a block corresponding to any one of the four ways. Any one of a plurality of sets included in the block is output to the control portion 21 through the input/output portion 32 provided in any one of the element layers 30 in accordance with the address signal.

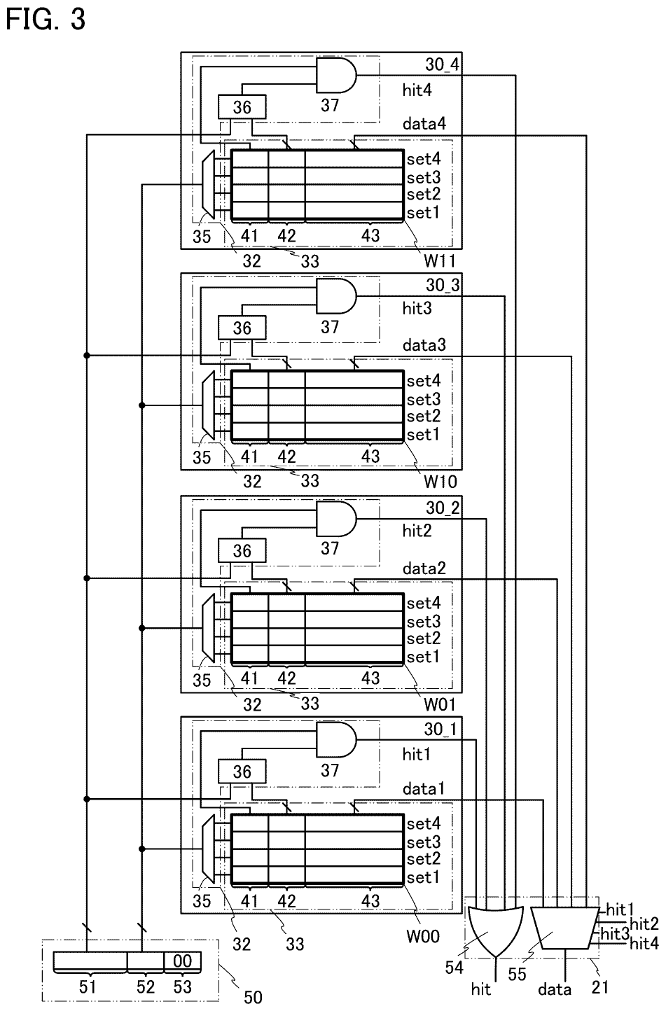

FIG. 3 illustrates a block diagram illustrating a structure example where blocks of different ways are stored in each of the element layers 30 illustrated in FIG. 2A and FIG. 2B. In FIG. 3, the blocks W00, W01, W10, and W11 are stored in the memory portions 33 of the element layers 30_1 to 30_4. The sets set1 to set4 included in each block include the identification information of the flag 41, the tag 42, and the data 43. In addition, decoders 35, comparators 36, and AND gates 37 are illustrated as structure examples of the input/output portions 32 of the element layers 30_1 to 30_4.

FIG. 3 also illustrates an address signal 50 input to the input/output portions 32 of the element layers 30_1 to 30_4. A tag 51, a set 52, and an offset 53 are illustrated as the data field of the address signal 50. For example, data of N bits following M bits from the most significant bit of the address signal 50 can be the tag 51 and the set 52.

In the case where desired data is read, the set 52 is input to the decoders 35 of the element layers 30_1 to 30_4. Note that in the structure of FIG. 3, although the offset 53 is described as a 2-bit signal “00,” the offset 53 can be changed as appropriate depending on the number of words. The set 52 is a set selection signal that selects a set corresponding to the set 52 (any one of set1 to set4) in the blocks W00, W01, W10, and W11. The tag 42 of the selected set is input to the comparator 36 and is compared with the tag 51 of the address signal 50. In the case where the tag 42 of the selected set and the tag 51 of the address signal 50 match, whether data read by the AND gate 37 is effective or not is determined. When the data read by the AND gate 37 is effective, hit signals hit1 to hit4 are output from the element layers 30_1 to 304, respectively, as a cache hit.

The hit signals hit1 to hit4 that are output from the input/output portions 32 of the element layers 30_1 to 304, respectively, are input to an OR gate 54 of the control portion 21, and a hit signal hit including information on whether the hit signals hit1 to hit4 correspond to a cache hit or a cache miss is output in each way. Data data1 to data4 of sets hit in the element layers 30_1 to 30_4 are input to a multiplexer 55 of the control portion 21. The control portion 21 outputs data data selected in accordance with the hit signals hit1 to hit4.

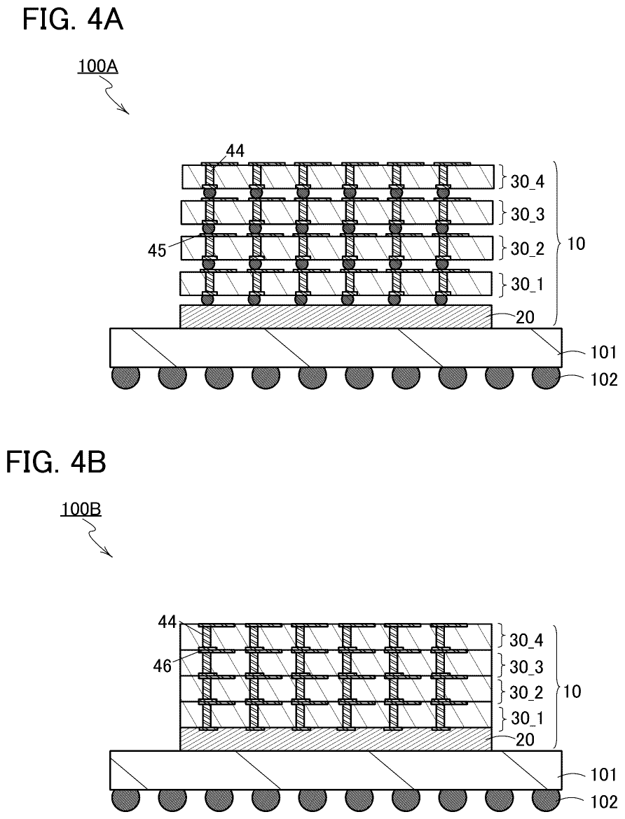

FIG. 4A and FIG. 4B illustrate examples of an integrated circuit (referred to as an IC chip) including the semiconductor device 10. The semiconductor device 10 can be one IC chip by mounting a plurality of dies on a packaging substrate. FIG. 4A and FIG. 4B illustrate examples of the structure.

A schematic cross-sectional view of an IC chip 100A illustrated in FIG. 4A includes the element layer 20 over a package substrate 101, and illustrates the semiconductor device 10 where the four element layers 30_1 to 30_4 are stacked over the element layer 20 as an example. Solder balls 102 for connecting the IC chip 100A to a printed circuit board or the like are provided on the package substrate 101. The element layers 30_1 to 30_4 can be connected to the element layer 20 via through electrodes 44 provided to penetrate the element layers 30_1 to 30_4. In addition, the element layers 30_1 to 30_4 can be electrically connected via metal bumps 45 (also referred to as micro-bumps) provided between the through electrodes 44 provided to penetrate the element layers 30_1 to 30_4.

As another example, a schematic cross-sectional view of an IC chip 100B illustrated in FIG. 4B includes the element layer 20 over the package substrate 101 and, for example, the four element layers 30_1 to 30_4 are stacked over the element layer 20. The element layers 30_1 to 30_4 are provided with the through electrodes 44 provided to penetrate the element layers 30. The element layers 301 to 30_4 are attached to each other using electrodes 46 provided to exposed to surfaces. As a technique electrically bonding different layers using the electrodes 46, Cu—Cu bonding can be used. The Cu—Cu bonding is a technique that establishes electrical conduction by connecting Cu (copper) pads.

In the case where the element layers 30 in each of which a memory cell that functions as a cache memory is provided are three-dimensionally stacked as illustrated in FIG. 4A and FIG. 4B, the element layers 30 are electrically connected to each other with a technique using through electrodes such as TSVs, a Cu—Cu direct bonding technique, or the like. In that case, a resistance component due to bonding between a Si die and a Si die is generated, and the resistance component between the element layer 20 and each of the element layer 30 in the upper layer and the element layer 30 in the lower layer varies.

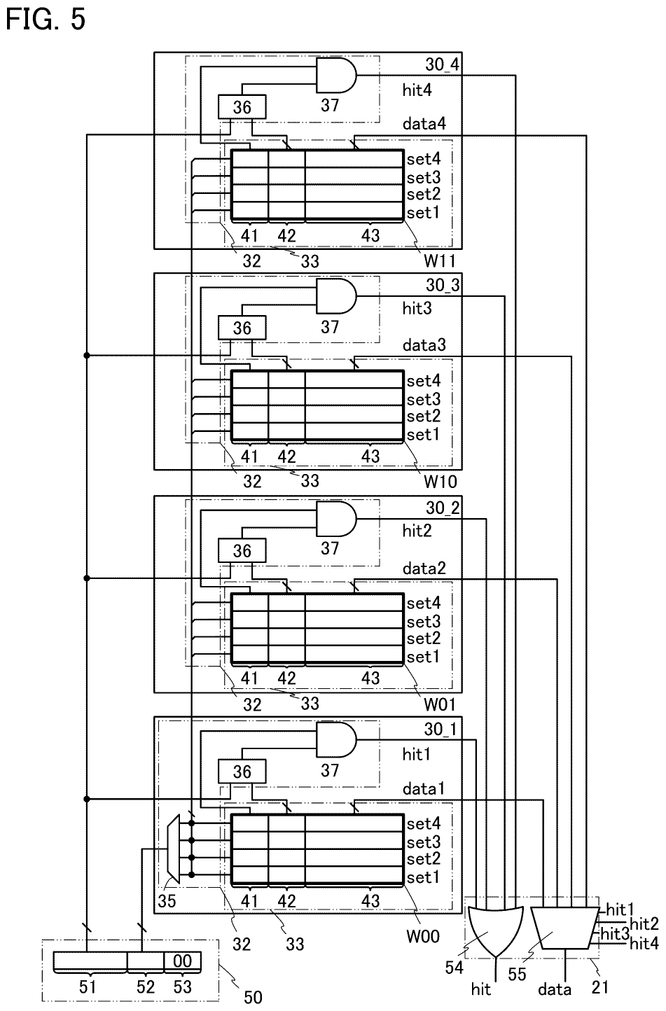

With a structure where data corresponding to any one of a plurality of ways is stored in the memory portion 33 of each of the element layers 30 and is output through the input/output portion as in one embodiment of the present invention, a variation in signal delay can be reduced. Access to each element layer, comparison of tags in each element layer, output of hit signals, output of data, and the like are performed based on the set signals. When the element layers where cache memories are separately provided are made to correspond to the blocks of the ways, a variation in length of a path between the control portion 21 and the element layer 30 can be reduced regardless of the set signals. In other words, imbalance of access to the element layer in the upper layer or access to the element layer in the lower layer can be reduced. In addition, delay in each way in each element layer can be reduced. Furthermore, a structure can also be employed in which, as illustrated in FIG. 5, a decoded set selection signal is generated by the common decoder 35 for each way formed only in one layer (the element layer 301 in FIG. 5) and the set selection signal is supplied to each layer. With such a structure, the scale of a circuit formed in each layer can be reduced, the chip can be downsized, and the power consumption of the decoder can be reduced.

This embodiment can be implemented in combination with the other embodiments described in this specification as appropriate.

### Embodiment 2

In this embodiment, modification examples of the semiconductor device described in the above embodiment are described. Note that components described in Embodiment 1 are denoted by common reference numerals, and description thereof is omitted.

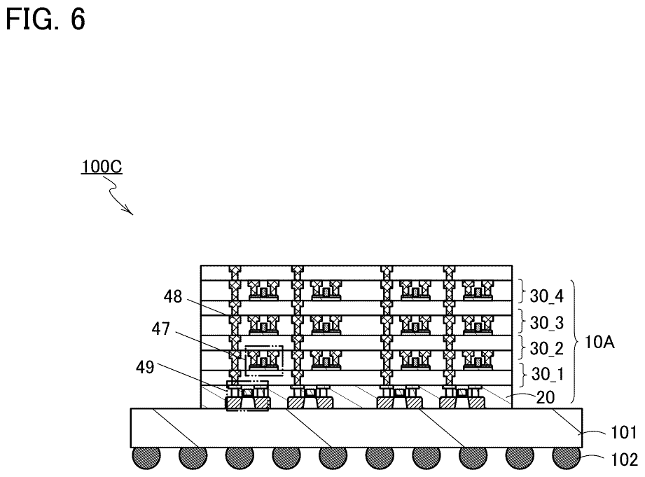

FIG. 6 is a schematic cross-sectional view for illustrating a semiconductor device that is different from the schematic cross-sectional view of the semiconductor device 10 mounted on each of the IC chips illustrated in FIG. 4A and FIG. 4B. A structure is illustrated in which in an IC chip 100C illustrated in FIG. 6, a semiconductor device 10A includes Si transistors 49 in the element layer 20 and OS transistors 47 are included in each of the element layers 30_1 to 30_4. Electrodes 48 for electrically connecting the element layer 20 and the element layers 30_1 to 30_4 can be provided in a step of manufacturing the Si transistors 49 or the OS transistors 47.

The structure in FIG. 6 can be a monolithic structure where a technique using through electrodes such as TSVs or a Cu—Cu direct bonding technique is not used for connection between the element layer 20 including the Si transistors 49 and the element layers 30_1 to 30_4 including the OS transistors. The element layers 30_1 to 30_4 over the element layer 20 can have a structure where wirings provided together with the OS transistors 47 included in the element layers 30_1 to 30_4 are used as the electrodes 48 for being connected to the element layers in the upper layers or the lower layers.

The interval between the wirings provided together with the OS transistors 47 can be more microfabricated than the through electrodes used in the TSVs or the Cu—Cu direct bonding technique. Thus, in the structure of the semiconductor device 10A illustrated in FIG. 6, the number of electrodes for being connected to the element layers in the upper layers or the lower layers can be increased. Accordingly, the number of wirings (the number of signal lines) in the memory portions that function as cache memories provided in the element layers 30_1 to 30_4 and the control portion 21 provided in the element layer 20 can be increased. In other words, the number of channels between each of the cache memories and the control portion can be increased. Therefore, the transfer amount (bandwidth) of signals transmitted and received between the element layer 20 and the element layer 30 can be increased. The increase in the bandwidth can increase the data transfer amount per unit time.

Examples of a metal oxide employed for the OS transistor include indium oxide, gallium oxide, and zinc oxide. In addition, the metal oxide preferably contains two or three selected from indium, an element M, and zinc. Note that the element M is one or more kinds selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Alternatively, it is preferable to use an oxide containing indium (In), gallium (Ga), zinc (Zn), and tin (Sn) (also referred to as IGZTO).

In addition, the metal oxide employed for the OS transistor may include two or more metal oxide layers with different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and provided over the first metal oxide layer can be suitably used.

Alternatively, a stacked-layer structure or the like of any one selected from indium oxide, indium gallium oxide, and IGZO, and any one selected from IAZO, IAGZO, and ITZO may be used, for example.

Note that the metal oxide employed for the OS transistor preferably has crystallinity. As an oxide semiconductor having crystallinity, a CAAC (c-axis aligned crystalline)-OS, an nc (nanocrystalline)-OS, and the like can be given. When the oxide semiconductor having crystallinity is used, a highly reliable semiconductor device can be provided.

In addition, the OS transistor stably operates even in a high-temperature environment and has small fluctuation in characteristics. For example, off-state current hardly increases even in the high-temperature environment. Specifically, the off-state current hardly increases even at environmental temperature higher than or equal to room temperature and lower than or equal to 200° C. Furthermore, on-state current is unlikely to decrease even in the high-temperature environment. Thus, a memory cell including the OS transistor stably operates even in the high-temperature environment and has high reliability.

A NOSRAM is preferable as a memory cell that can be employed in the element layer 30 including the OS transistor. NOSRAM (registered trademark) is an abbreviation for “Nonvolatile Oxide Semiconductor Random Access Memory (RAM).” The memory cell of the NOSRAM is a 2-transistor (2T) or 3-transistor (3T) gain cell.

The OS transistor has extremely low current that flows between a source and a drain in an off state, that is, leakage current. The NOSRAM can be used as a nonvolatile memory by holding electric charge corresponding to data in the memory cell with the use of characteristics of extremely low leakage current. In particular, the NOSRAM is capable of reading retained data without destruction (non-destructive reading), and thus is suitable for arithmetic processing in which only data reading operation is repeated many times.

Here, a structure example of the memory portion 33 in which the NOSRAM is used as a memory cell is described.

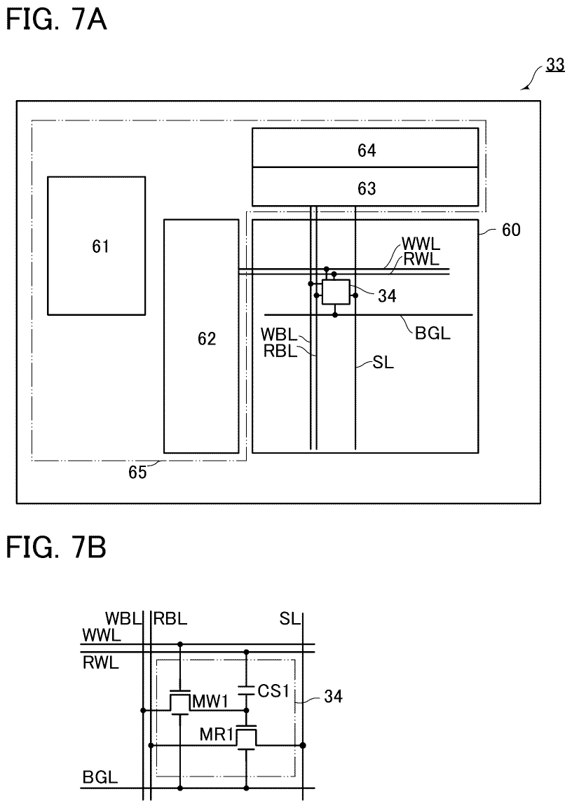

The memory portion 33 illustrated in FIG. 7A includes a memory cell array 60 and a peripheral circuit 65. A control circuit 61, a row circuit 62, a column circuit 63, and an input/output circuit 64 are provided as the peripheral circuit 65.

The memory cell array 60 includes the memory cell 34, a word line RWL, a word line WWL, a bit line RBL, a bit line WBL, a source line SL, and a wiring BGL. Note that the word line RWL and the word line WWL are referred to as a read word line RWL and a write word line WWL, respectively, in some cases. The bit line RBL and the bit line WBL are referred to as a read bit line RBL and a write bit line WBL, respectively, in some cases.

The control circuit 61 collectively controls the whole memory portion 33 and performs data writing and data reading. The control circuit 61 processes command signals from the outside (e.g., a chip enable signal, a write enable signal, and the like) and generates control signals for other circuits in the peripheral circuit 65.

The row circuit 62 has a function of selecting a row to be accessed. For example, the row circuit 62 includes a row decoder and a word line driver. The column circuit 63 has a function of precharging the bit lines WBL and RBL, a function of writing data to the bit line WBL, a function of amplifying data of the bit line RBL, a function of reading data from the bit line RBL, and the like. The input/output circuit 64 has a function of retaining write data, a function of retaining read data, and the like.

The structure of the peripheral circuit 65 is changed as appropriate depending on the structure, reading method, writing method, and the like of the memory cell array 60. In addition, a structure where part of the peripheral circuit 65 is provided in the element layer 20 is preferable.

FIG. 7B illustrates a circuit structure example of the memory cell 34. Here, the memory cell 34 is a 2-transistor (2T) gain cell. The memory cell 34 includes transistors MW1 and MR1 and a capacitor CS1. The transistor MW1 is a write transistor and the transistor MR1 is a read transistor. Back gates of the transistors MW1 and MR1 are electrically connected to the wiring BGL.

Since the read transistor is composed of an OS transistor, the memory cell 34 does not consume power for data retention. Thus, the memory cell 34 is a low-power memory cell that can retain data for a long time, and the memory portion 33 can be used as a nonvolatile memory device.

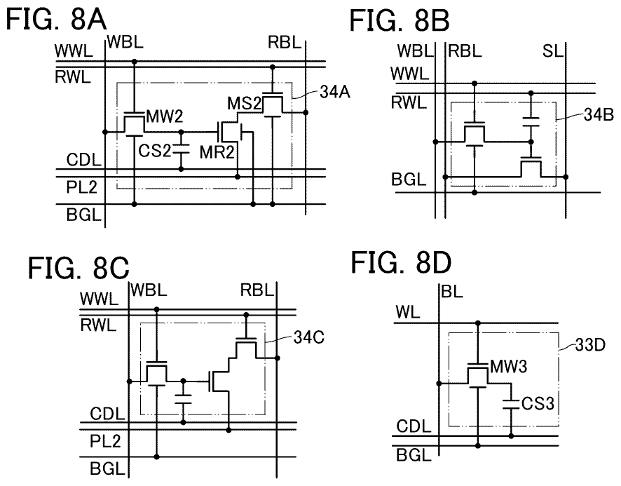

Other structure examples of memory cells are described with reference to FIG. 8A to FIG. 8D.

A memory cell 34A illustrated in FIG. 8A is a 3T gain cell, which includes transistors MW2, MR2, and MS2, and a capacitor CS2. The transistors MW2, MR2, and MS2 are a write transistor, a read transistor, and a selection transistor, respectively. Back gates of the transistors MW2, MR2, and MS2 are electrically connected to the wiring BGL. The memory cell 34A is electrically connected to the word lines RWL and WWL, the bit lines RBL and WBL, a capacitor line CDL, and a power supply line PL2. For example, voltage GND (low-level-side power supply voltage) is input to the capacitor line CDL and the power supply line PL2.

FIG. 8B illustrates another structure example of a 2T gain cell. In a memory cell 34B illustrated in FIG. 8B, a read transistor is composed of an OS transistor that does not have a back gate.

FIG. 8C illustrates another structure example of a 3T gain cell. In a memory cell 34C illustrated in FIG. 8C, a read transistor and a selection transistor are each composed of an OS transistor that does not have a back gate.

In each of the above gain cells, a bit line serving as both the bit line RBL and the bit line WBL may be provided.

In addition, although the NOSRAM is described as an example of a structure applicable to the memory cell 34, another structure may be employed as long as it is a memory cell that can be formed using an OS transistor. For example, a DOSRAM that is a memory circuit including an OS transistor may be used. DOSRAM (registered trademark) is an abbreviation for “Dynamic Oxide Semiconductor RAM,” which refers to a RAM including a 1T (transistor) 1C (capacitor) memory cell. The DOSRAM is a DRAM formed using an OS transistor, and the DOSRAM is a memory that temporarily stores information transmitted from the outside. The DOSRAM is a memory utilizing low off-state current of the OS transistor.

FIG. 8D illustrates an example of a 1T1C (capacitor) memory cell. A memory cell 34D illustrated in FIG. 8D is electrically connected to a word line WL, a bit line BL, the capacitor line CDL, and the wiring BGL. The memory cell 34D includes a transistor MW3 and a capacitor CS3. A back gate of the transistor MW3 is electrically connected to the wiring BGL.

In the case where the memory cell 34 is a NOSRAM or a DOSRAM, another portion of the peripheral circuit or the like is preferably power-gated with voltage that turns off a transistor corresponding to an access transistor (the transistor MW1 in FIG. 7B) applied to the wiring WWL connected to a gate of the transistor. With this structure, the supply of power supply voltage can be stopped while data is stored in the memory cell 34.

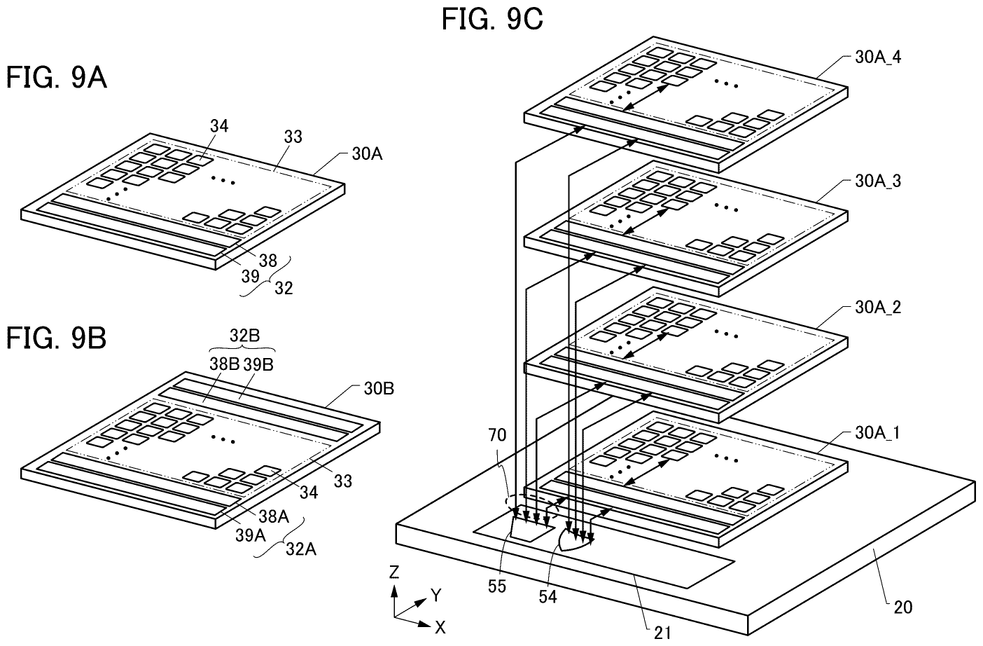

In addition, FIG. 9A illustrates a schematic perspective view for illustrating another structure example of the element layer 30 in Embodiment 1. In an element layer 30A illustrated in FIG. 9A, a structure is illustrated in which a read circuit 38 and an I/O 39 (an input/output circuit) are included as the input/output portion 32.

The read circuit 38 includes a circuit such as a sense amplifier. The read circuit 38 is a circuit that outputs a signal (an analog signal) output from the memory cell 34 as read data that is digital data. In addition, the I/O 39 is a circuit for inputting and outputting write data and read data from the outside of a chip.

The element layer 30A including the OS transistor can transmit and receive signals through an electrode that can be more microfabricated than the through electrodes used in the TSVs or the Cu—Cu direct bonding technique. In the structure in FIG. 9A, the number of electrodes for being connected to the element layer in the upper layer or the lower layer can be increased. Accordingly, the transfer amount (bandwidth) of signals transmitted and received can be increased, and the data transfer amount per unit time can be increased.

FIG. 9B illustrates a schematic perspective view in which a plurality of input/output portions 32A and 32B are included in the structure of the element layer 30A illustrated in FIG. 9A. In the element layer 30B illustrated in FIG. 9B, a structure is illustrated in which the read circuit 38 and the I/O 39 (the input/output circuit) are included as the input/output portion 32.

In the structure of an element layer 30B illustrated in FIG. 9B, the number of electrodes for being connected to the element layer in the upper layer or the lower layer can be further increased. Thus, the number of channels between the memory portion that functions as a cache memory provided in the element layer 30B and the control portion provided in the element layer 20 (not illustrated) can be increased. Accordingly, the transfer amount (bandwidth) of signals transmitted and received can be increased, and the data transfer amount per unit time can be increased.

In addition, FIG. 9C is a diagram in which the element layers 30A (element layers 30A_1 to 30A_4) illustrated in FIG. 9A are stacked over the element layer 20 including the control portion 21 and signals 70 that are input and output are indicated by arrows. When the number of signals for being connected to the element layers in the upper layers or the lower layers is increased, the number of channels between the memory portion and the control portion provided in the element layer 20 (not illustrated) can be increased.

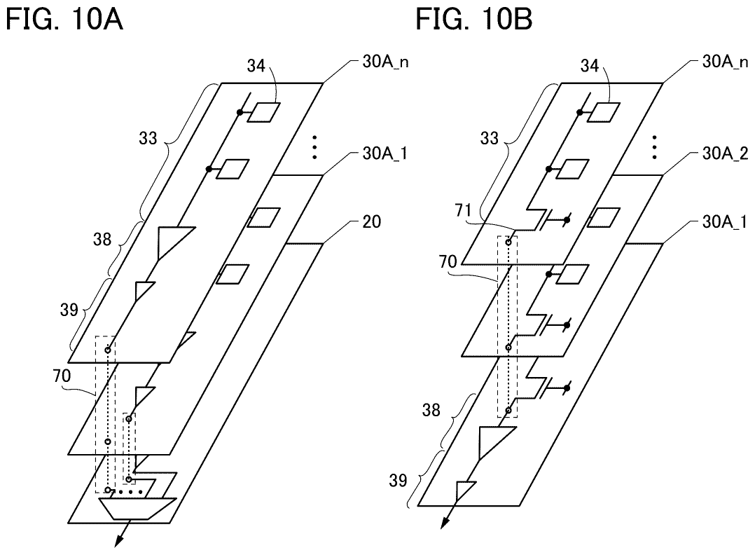

For example, in the case where regions in which the read circuit 38 and the I/O 39 are stacked and provided to overlap one another in element layers 30A_1 to 30A_n as illustrated in FIG. 10A, the number of the signals 70 for being connected to the element layers in the upper layers or the lower layers can be achieved by placing the electrodes for being connected to the element layers in the upper layers or the lower layers at high density.

The element layer 30A including the OS transistor can transmit and receive signals through an electrode that can be more microfabricated than the through electrodes used in the TSVs or the Cu—Cu direct bonding technique. Thus, in the structures in FIG. 9C and FIG. 10A, the number of electrodes for being connected to the element layers in the upper layers or the lower layers can be increased. Accordingly, the transfer amount (bandwidth) of signals transmitted and received can be increased, and the data transfer amount per unit time can be increased.

Alternatively, a structure illustrated in FIG. 10B may be employed. In the structure in FIG. 10B, the element layer 30_1 is provided with the read circuit 38 and the I/O 39, and a transistor 71 that functions as a switch is provided between the read circuit 38 and the memory cell 34 in each of the element layers 30A_1 to 30A_n. With this structure, the number of electrodes for being connected to the element layers in the upper layers or the lower layers can be further increased. Accordingly, the transfer amount (bandwidth) of signals transmitted and received can be increased, and the data transfer amount per unit time can be increased.

Alternatively, a structure where the structure in FIG. 10A and the structure in FIG. 10B are used in combination is also effective. For example, it is preferable to employ a structure where a read circuit for the flag 41 and the tag 42 in FIG. 3 is formed as the read circuit 38 in FIG. 10A, the comparator 36 and the AND gate 37 are formed in each layer as the I/O 39 in FIG. 10A, and the OR gate 54 is formed in the element layer 30A_1, a read circuit for the data 43 in FIG. 3 is used as the read circuit 38 in FIG. 10B, and the multiplexer 55 is used as the I/O 39 in FIG. 10B. With such a structure, the scale of a circuit formed in each layer can be reduced, the chip can be downsized, and the power consumption of the read circuit can be reduced.

This embodiment can be implemented in combination with the other embodiments described in this specification as appropriate.

### Embodiment 3

In this embodiment, structures of transistors that can be used in the semiconductor device described in the above embodiment will be described. For example, a structure in which transistors having different electrical characteristics are stacked and provided will be described. With such a structure, the degree of freedom in design of a semiconductor device can be increased. In addition, providing transistors having different electrical characteristics to be stacked can increase the integration degree of the semiconductor device.

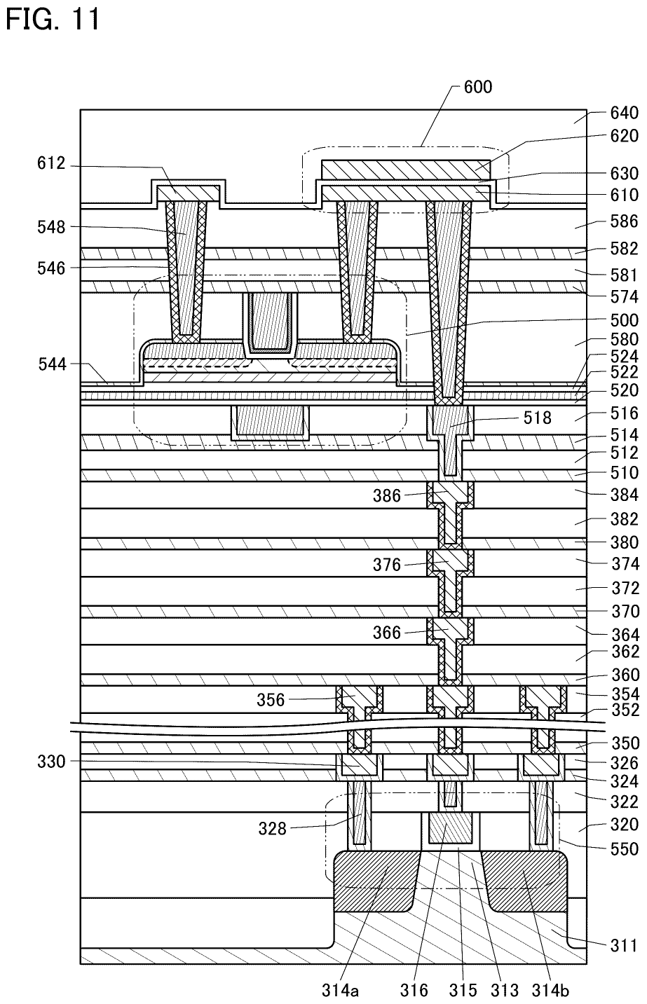

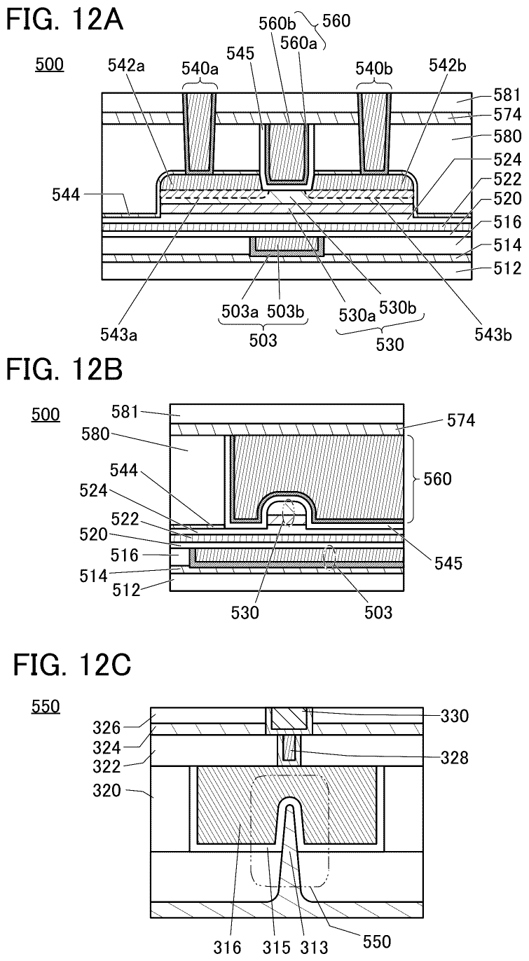

FIG. 11 illustrates part of a cross-sectional structure of a semiconductor device. The semiconductor device illustrated in FIG. 11 includes a transistor 550, a transistor 500, and a capacitor 600. FIG. 12A is a cross-sectional view of the transistor 500 in a channel length direction, FIG. 12B is a cross-sectional view of the transistor 500 in a channel width direction, and FIG. 12C is a cross-sectional view of the transistor 550 in a channel width direction. For example, the transistor 500 corresponds to the Si transistor described in the above embodiment, and the transistor 550 corresponds to an OS transistor.

In FIG. 11, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 12C, in the transistor 550, a top surface and a side surface in the channel width direction of the semiconductor region 313 are covered with the conductor 316 with the insulator 315 therebetween. The use of such a Fin-type transistor as the transistor 550 can increase the effective channel width and thus improve on-state characteristics of the transistor 550. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, a semiconductor material such as silicon containing the element that imparts n-type conductivity, such as arsenic or phosphorus, or the element that imparts p-type conductivity, such as boron, or a conductive material such as a metal material, an alloy material, or a metal oxide material can be used.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (silicon on Insulator) substrate or the like.

In addition, as the SOI substrate, the following substrate may be used: a SIMOX (Separation by Implanted Oxygen) substrate that is formed in such a manner that after an oxygen ion is implanted into a mirror-polished wafer, an oxide layer is formed at a certain depth from a surface and defects generated in a surface layer are eliminated by high-temperature annealing, or an SOI substrate formed by using a Smart-Cut method in which a semiconductor substrate is cleaved by utilizing growth of a minute void, which is formed by implantation of a hydrogen ion, by heat treatment; an ELTRAN method (a registered trademark: Epitaxial Layer Transfer); or the like. A transistor formed using a single crystal substrate contains a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, a top surface of the insulator 322 may be planarized by planarization treatment using a chemical mechanical polishing (CMP) method or the like to increase planarity.

In addition, for the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, for example, silicon nitride formed by a CVD method can be used. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

In addition, a conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 11, an insulator 350, an insulator 352, and an insulator 354 are sequentially stacked and provided. Furthermore, a conductor 356 is formed in the insulator 350, the insulator 352, and the insulator 354. The conductor 356 has a function of a plug connected to the transistor 550 or a wiring. Note that the conductor 356 can be provided using a material similar to those for the conductor 328 and the conductor 330.

Note that for example, as the insulator 350, like the insulator 324, an insulator having a barrier property against hydrogen is preferably used. Furthermore, the conductor 356 preferably includes a conductor having a barrier property against hydrogen. In particular, the conductor having a barrier property against hydrogen is formed in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. In addition, by stacking tantalum nitride and tungsten, which has high conductivity, diffusion of hydrogen from the transistor 550 can be inhibited while the conductivity as a wiring is kept. In that case, a structure in which a tantalum nitride layer having a barrier property against hydrogen is in contact with the insulator 350 having a barrier property against hydrogen is preferable.

A wiring layer may be provided over the insulator 354 and the conductor 356. For example, in FIG. 11, an insulator 360, an insulator 362, and an insulator 364 are sequentially stacked and provided. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, as the insulator 360, like the insulator 324, an insulator having a barrier property against hydrogen is preferably used. Furthermore, the conductor 366 preferably includes a conductor having a barrier property against hydrogen. In particular, the conductor having a barrier property against hydrogen is formed in an opening portion of the insulator 360 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 364 and the conductor 366. For example, in FIG. 11, an insulator 370, an insulator 372, and an insulator 374 are sequentially stacked and provided. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, as the insulator 370, like the insulator 324, an insulator having a barrier property against hydrogen is preferably used. Furthermore, the conductor 376 preferably includes a conductor having a barrier property against hydrogen. In particular, the conductor having a barrier property against hydrogen is formed in an opening portion of the insulator 370 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 374 and the conductor 376. For example, in FIG. 11, an insulator 380, an insulator 382, and an insulator 384 are sequentially stacked and provided. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, as the insulator 380, like the insulator 324, an insulator having a barrier property against hydrogen is preferably used. Furthermore, the conductor 386 preferably includes a conductor having a barrier property against hydrogen. In particular, the conductor having a barrier property against hydrogen is formed in an opening portion of the insulator 380 having a barrier property against hydrogen. With this structure, the transistor 550 and the transistor 500 can be separated with a barrier layer, so that hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device according to this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are sequentially stacked and provided over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Therefore, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

In addition, for the film having a barrier property against hydrogen, a metal oxide such as aluminum oxide, hafnium oxide, or tantalum oxide is preferably used for each of the insulator 510 and the insulator 514, for example.

In particular, aluminum oxide has an excellent blocking effect that prevents passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after a manufacturing process of the transistor. In addition, release of oxygen from the oxide included in the transistor 500 can be inhibited. Therefore, aluminum oxide is suitably used for a protective film of the transistor 500.

In addition, for each of the insulator 512 and the insulator 516, a material similar to that for the insulator 320 can be used, for example. Furthermore, when a material with comparatively low permittivity is used for these insulators, parasitic capacitance generated between wirings can be reduced. A silicon oxide film, a silicon oxynitride film, or the like can be used for each of the insulator 512 and the insulator 516, for example.

Furthermore, a conductor 518, a conductor included in the transistor 500 (a conductor 503, for example), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated with a layer having a barrier property against oxygen, hydrogen, and water, so that hydrogen diffusion from the transistor 550 into the transistor 500 can be inhibited.

The transistor 500 is provided above the insulator 516.

As illustrated in FIG. 12A and FIG. 12B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; an oxide 530a positioned over the insulator 524; an oxide 530b positioned over the oxide 530a; a conductor 542a and a conductor 542b positioned apart from each other over the oxide 530b; an insulator 580 that is positioned over the conductor 542a and the conductor 542b and is provided with an opening formed to overlap a region between the conductor 542a and the conductor 542b; an insulator 545 positioned on a bottom surface and a side surface of the opening; and a conductor 560 positioned on a formation surface of the insulator 545.

In addition, as illustrated in FIG. 12A and FIG. 12B, an insulator 544 is preferably positioned between the insulator 580 and the oxide 530a, the oxide 530b, the conductor 542a, and the conductor 542b. Furthermore, as illustrated in FIG. 12A and FIG. 12B, the conductor 560 preferably includes a conductor 560a provided inside the insulator 545 and a conductor 560b provided to be embedded inside the conductor 560a. Moreover, as illustrated in FIG. 12A and FIG. 12B, an insulator 574 is preferably positioned over the insulator 580, the conductor 560, and the insulator 545.

Note that in this specification and the like, the oxide 530a and the oxide 530b are sometimes collectively referred to as an oxide 530.

Note that the transistor 500 is illustrated to have a structure in which two layers, the oxide 530a and the oxide 530b, are stacked in the region where the channel is formed and its vicinity; however, the present invention is not limited thereto. For example, a structure may be employed in which a single layer of the oxide 530b or a stacked-layer structure of three or more layers is provided.

In addition, although the conductor 560 has a stacked-layer structure of two layers in the transistor 500, the present invention is not limited thereto. For example, the conductor 560 may have a single-layer structure or a stacked-layer structure of three or more layers. Furthermore, the transistor 500 illustrated in FIG. 11 and FIG. 12A is an example and the structure is not limited thereto; an appropriate transistor is used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, which results in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not have a region overlapping the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 sometimes functions as a first gate (also referred to as top gate) electrode. In addition, the conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is positioned to overlap the oxide 530 and the conductor 560. Thus, when a potential is applied to the conductor 560 and the conductor 503, an electric field generated from the conductor 560 and an electric field generated from the conductor 503 are connected, so that the channel formation region formed in the oxide 530 can be covered.

In this specification and the like, a transistor structure where a channel formation region is electrically surrounded by an electric field of a first gate electrode is referred to as a surrounded channel (S-channel) structure. In addition, the S-channel structure disclosed in this specification and the like has a structure different from a Fin-type structure and a planar structure. Meanwhile, the S-channel structure disclosed in this specification and the like can also be regarded as a kind of Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor has the S-channel structure, the channel formation region can be electrically surrounded. Note that since the S-channel structure is a structure where the channel formation region is electrically surrounded, it can also be said that the S-channel structure is a structure substantially equivalent to a GAA (Gate All Around) structure or an LGAA (Lateral Gate All Around) structure. When the transistor has the S-channel structure, the GAA structure, or the LGAA structure, a channel formation region that is formed at an interface between the oxide 530 and a gate insulator or in the vicinity of the interface can be the entire bulk of the oxide 530. Accordingly, the density of current flowing through the transistor can be improved, which can be expected to improve the on-state current of the transistor or increase the field-effect mobility of the transistor.

In addition, the conductor 503 has a structure similar to that of the conductor 518; a conductor 503a is formed in contact with an inner wall of an opening in the insulator 514 and the insulator 516, and a conductor 503b is formed on the inner side. Note that although the conductor 503a and the conductor 503b are stacked in the transistor 500, the present invention is not limited thereto. For example, the conductor 503 may be provided as a single layer or to have a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities are less likely to pass) is preferably used. Alternatively, it is preferable to use a conductive material that has a function of inhibiting diffusion of oxygen (e.g., at least one of an oxygen atom, an oxygen molecule, and the like) (through which oxygen is less likely to pass). Note that in this specification, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator containing oxygen more than that in the stoichiometric composition is preferably used as the insulator 524 in contact with the oxide 530. Such oxygen is easily released from the insulator by heating. In this specification and the like, oxygen released by heating is sometimes referred to as “excess oxygen.” That is, a region containing excess oxygen (also referred to as an “excess-oxygen region”) is preferably formed in the insulator 524. When such an insulator containing excess oxygen is provided in contact with the oxide 530, oxygen vacancies (Vo) in the oxide 530 can be reduced and the reliability of the transistor 500 can be improved. Note that when hydrogen enters the oxygen vacancies in the oxide 530, such defects (hereinafter, referred to as VoH in some cases) serve as donors and generate electrons serving as carriers in some cases. In addition, in some cases, bonding of part of hydrogen to oxygen bonded to a metal atom generates electrons serving as carriers. Thus, a transistor using an oxide semiconductor that contains a large amount of hydrogen is likely to be normally-on (a state where a channel exists even without application of voltage to a gate electrode and current flows through the transistor). Moreover, hydrogen in an oxide semiconductor is easily transferred by stress such as heat or an electric field; thus, the reliability of the transistor might be reduced when the oxide semiconductor contains a large amount of hydrogen. In one embodiment of the present invention, VoH in the oxide 530 is preferably reduced as much as possible so that the oxide 530 becomes a highly purified intrinsic or substantially highly purified intrinsic oxide. It is important to remove impurities such as moisture and hydrogen in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose VoH is sufficiently reduced. When an oxide semiconductor with sufficiently reduced impurities such as VoH is used for a channel formation region of a transistor, stable electrical characteristics can be given.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of higher than or equal to 100° C. and lower than or equal to 700° C., or higher than or equal to 100° C. and lower than or equal to 400° C.

In addition, any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the oxide 530 or an insulator in the vicinity of the oxide 530 in some cases. In other cases, part of hydrogen is gettered by a conductor 542.

In addition, for the microwave treatment, for example, it is suitable to use an apparatus including a power supply that generates high-density plasma or an apparatus including a power supply that applies RF to a substrate side. For example, high-density oxygen radicals can be generated with the use of an oxygen-containing gas and high-density plasma, and by applying RF to the substrate side, the oxygen radicals generated by the high-density plasma can be efficiently introduced into the oxide 530 or the insulator in the vicinity of the oxide 530. Furthermore, pressure in the microwave treatment is higher than or equal to 133 Pa, preferably higher than or equal to 200 Pa, further preferably higher than or equal to 400 Pa. Moreover, as a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In addition, in the manufacturing process of the transistor 500, it is suitable to perform the heat treatment with the surface of the oxide 530 exposed. The heat treatment is performed at higher than or equal to 100° C. and lower than or equal to 450° C., further preferably higher than or equal to 350° C. and lower than or equal to 400° C., for example. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then heat treatment is performed in an atmosphere containing an oxidizing gas at higher than or equal to 10 ppm, higher than or equal to 1%, or higher than or equal to 10% in order to compensate for released oxygen. Alternatively, the heat treatment may be performed in such a manner that heat treatment is performed in an atmosphere containing an oxidizing gas at higher than or equal to 10 ppm, higher than or equal to 1%, or higher than or equal to 10%, and then heat treatment is successively performed in a nitrogen gas or inert gas atmosphere.

Note that oxygen adding treatment performed on the oxide 530 can promote reaction in which oxygen vacancies in the oxide 530 are filled with supplied oxygen, i.e., reaction of “Vo+O→null.” Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen is less likely to pass).

When the insulator 522 has a function of inhibiting diffusion of oxygen, impurities, or the like, oxygen contained in the oxide 530 is not diffused into the insulator 520 side, which is preferable. Furthermore, the conductor 503 can be inhibited from reacting with oxygen contained in the insulator 524, the oxide 530, or the like.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current might arise because of a thinner gate insulating film. When a high-k material is used for an insulator functioning as the gate insulating film, a gate potential during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is less likely to pass). Aluminum oxide, hafnium oxide, an oxide containing aluminum and hafnium (hafnium aluminate), or the like is preferably used for the insulator containing an oxide of one or both of aluminum and hafnium. In the case where the insulator 522 is formed using such a material, the insulator 522 functions as a layer that inhibits release of oxygen from the oxide 530 or mixing of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

In addition, it is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and high relative permittivity.

Note that in the transistor 500 in FIG. 12A and FIG. 12B, the insulator 520, the insulator 522, and the insulator 524 are illustrated as the second gate insulating film having a stacked-layer structure of three layers; however, the second gate insulating film may be a single layer or may have a stacked-layer structure of two layers or four or more layers. In that case, without limitation to a stacked-layer structure formed of the same material, a stacked-layer structure formed of different materials may be employed.

In the transistor 500, a metal oxide functioning as an oxide semiconductor is used as the oxide 530 including the channel formation region. For example, as the oxide 530, a metal oxide such as an In-M-Zn oxide (the element M is one kind or a plurality of kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor will be described in detail in another embodiment.

In addition, as the metal oxide functioning as the channel formation region in the oxide 530, a metal oxide whose bandgap is wider than or equal to 2 eV, preferably wider than or equal to 2.5 eV is preferably used. The use of a metal oxide having such a wide bandgap can reduce the off-state current of the transistor.

When the oxide 530 includes the oxide 530a under the oxide 530b, it is possible to inhibit diffusion of impurities into the oxide 530b from the components formed below the oxide 530a.

Note that the oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element Min the metal oxide used as the oxide 530b is preferably higher than the atomic ratio of In to the element M in the metal oxide used as the oxide 530a.

In addition, the energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at an interface between the oxide 530a and the oxide 530b is preferably made low.

Specifically, when the oxide 530a and the oxide 530b contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used for the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing the above metal element; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 12A, a stacked-layer structure of two or more layers may be employed. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material containing indium oxide, tin oxide, or zinc oxide may be used.

In addition, as illustrated in FIG. 12A, a region 543a and a region 543b are sometimes formed as low-resistance regions at an interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. In this case, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

When the insulator 544 is included, diffusion of impurities such as water and hydrogen contained in the insulator 580 into the oxide 530b can be inhibited. Furthermore, oxidation of the conductor 542 due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as leakage current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 that functions as the first gate electrode and has a two-layer structure is illustrated in FIG. 12A and FIG. 12B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. Alternatively, for the conductor 560a, the oxide semiconductor that can be used as the oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus a conductor having high conductivity is preferably used. For example, a conductive material containing tungsten, copper, or aluminum as its main component can be used. Moreover, the conductor 560b may have a stacked-layer structure, for example, a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween. The structures of the conductor 540a and the conductor 540b are similar to those of a conductor 546 and a conductor 548 that will be described later.

An insulator 582 is provided over the insulator 581. A substance having a barrier property against oxygen, hydrogen, or the like is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Therefore, aluminum oxide is suitably used for the protective film of the transistor 500.

In addition, an insulator 586 is provided over the insulator 582. For the insulator 586, a material similar to that for the insulator 320 can be used. Furthermore, when a material with comparatively low permittivity is used for these insulators, parasitic capacitance between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using materials similar to those for the conductor 328 and the conductor 330.

In addition, after the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. Note that when an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the manufacturing steps of the transistor 500. Note that the insulator having a high barrier property against hydrogen or water is formed using a material similar to that for the insulator 522 or the insulator 514, for example.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to employ a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are illustrated in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed at the same time as another component such as a conductor, copper (Cu), aluminum (Al), or the like, which is a low-resistance metal material, may be used.

An insulator 640 is provided over the conductor 620 and the insulator 630. The insulator 640 can be provided using a material similar to that for the insulator 320. In addition, the insulator 640 may function as a planarization film that covers an uneven shape therebelow.

With the use of this structure, a semiconductor device using a transistor including an oxide semiconductor can be miniaturized or highly integrated.

As a substrate that can be used for the semiconductor device according to one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (silicon on Insulator) substrate, or the like can be used. Alternatively, a plastic substrate having heat resistance to processing temperature in this embodiment may be used. Examples of the glass substrate include barium borosilicate glass, aluminosilicate glass, aluminoborosilicate glass, and soda lime glass. Alternatively, crystallized glass or the like can be used.

Alternatively, a flexible substrate; an attachment film; paper or a base film including a fibrous material; or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic evaporated film, and paper. In particular, the use of a semiconductor substrate, a single crystal substrate, an SOI substrate, or the like for the manufacture of transistors enables the manufacture of small-sized transistors with a small variation in characteristics, size, shape, or the like and high current capability. When a circuit is formed with such transistors, lower power consumption of the circuit or higher integration of the circuit can be achieved.

Alternatively, a flexible substrate may be used as the substrate, and a transistor, a resistor, a capacitor, and/or the like may be formed directly on the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. Note that as the separation layer, a stacked-layer structure of a tungsten film and a silicon oxide film that are inorganic films, a structure in which an organic resin film of polyimide or the like is formed over a substrate, a silicon film containing hydrogen, or the like can be used, for example.

That is, a semiconductor device may be formed over one substrate and then transferred to another substrate. Examples of a substrate to which a semiconductor device is transferred include, in addition to the above substrates over which transistors can be formed, a paper substrate, a cellophane substrate, an aramid film substrate, a polyimide film substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), or the like), a leather substrate, and a rubber substrate. With the use of these substrates, the manufacture of a flexible semiconductor device, the manufacture of a robust semiconductor device, provision of high heat resistance, a reduction in weight, or a reduction in thickness can be achieved.

Providing a semiconductor device over a flexible substrate can inhibit an increase in weight and can provide a robust semiconductor device.

Note that the transistor 550 illustrated in FIG. 11 is an example and the structure is not limited thereto; an appropriate transistor is used in accordance with a circuit structure, a driving method, or the like. For example, when the semiconductor device is a circuit having single polarity that is composed of only OS transistors, which means the same-polarity transistors such as n-channel transistors only, for example, the transistor 550 has a structure similar to that of the transistor 500.

The configuration, structure, method, and the like described in this embodiment can be used in combination as appropriate with the configurations, structures, methods, and the like described in the other embodiments, an example, and the like.

### Embodiment 4

In this embodiment, cross-sectional structure examples of semiconductor devices including the OS transistors described in the above embodiments, such as a DOSRAM and a NOSRAM, are described.

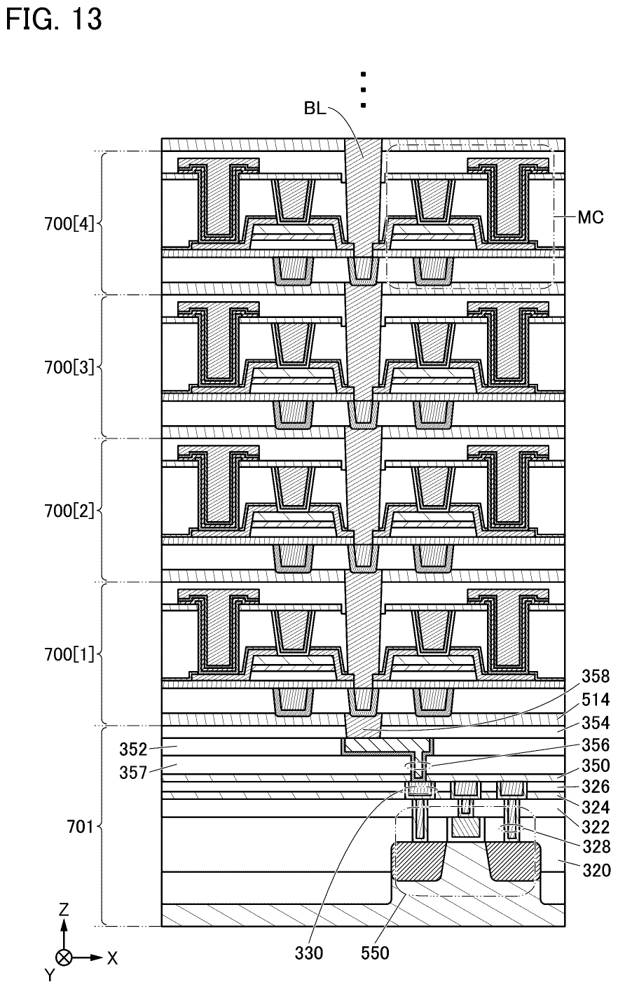

FIG. 13 illustrates a cross-sectional structure example of the case of using a DOSRAM circuit structure. In the example illustrated in FIG. 13, a memory layer 700[1] to a memory layer 700[4] are stacked over a driver circuit layer 701.

FIG. 13 also illustrates an example of the transistor 550 included in the driver circuit layer 701. As the transistor 550, the transistor 550 described in the above embodiment can be used.

Note that the transistor 550 illustrated in FIG. 13 is an example and is not limited to the structure illustrated therein; an appropriate transistor can be used in accordance with a circuit structure or a driving method.

A wiring layer provided with an interlayer film, a wiring, a plug, and the like may be provided between the driver circuit layer 701 and the memory layers 700 or between a k-th memory layer 700 and a (k+1)-th memory layer 700. Note that in this embodiment and the like, the k-th memory layer 700 is referred to as a memory layer 700[k], and the (k+1)-th memory layer 700 is referred to as a memory layer 700[k+1], in some cases. Here, k is an integer greater than or equal to 1 and less than or equal to N. In addition, in this embodiment and the like, the solutions of “k+α (α is an integer greater than or equal to 1)” and “k-α” are each an integer greater than or equal to 1 and less than or equal to N.

In addition, a plurality of wiring layers can be provided in accordance with design. Furthermore, in this specification and the like, a wiring and a plug electrically connected to the wiring may be a single component. That is, part of a conductor functions as a wiring in some cases, and part of a conductor functions as a plug in other cases.

For example, the insulator 320, the insulator 322, the insulator 324, and the insulator 326 are sequentially stacked and provided over the transistor 550 as interlayer films. In addition, the conductor 328 or the like is embedded in the insulator 320 and the insulator 322. Furthermore, the conductor 330 or the like is embedded in the insulator 324 and the insulator 326. Note that the conductor 328 and the conductor 330 each function as a contact plug or a wiring.

In addition, the insulators functioning as interlayer films may also function as planarization films that cover uneven shapes therebelow. For example, a top surface of the insulator 320 may be planarized by planarization treatment using a chemical mechanical polishing (CMP) method to increase planarity.

A wiring layer may be provided over the insulator 326 and the conductor 330. For example, in FIG. 13, the insulator 350, an insulator 357, the insulator 352, and the insulator 354 are sequentially stacked and provided over the insulator 326 and the conductor 330. Furthermore, the conductor 356 is formed in the insulator 350, the insulator 357, and the insulator 352. The conductor 356 functions as a contact plug or a wiring.

The insulator 514 included in the memory layer 700[1] is provided over the insulator 354. In addition, a conductor 358 is embedded in the insulator 514 and the insulator 354. The conductor 358 functions as a contact plug or a wiring. For example, a bit line BL and the transistor 550 are electrically connected through the conductor 358, the conductor 356, the conductor 330, and the like.

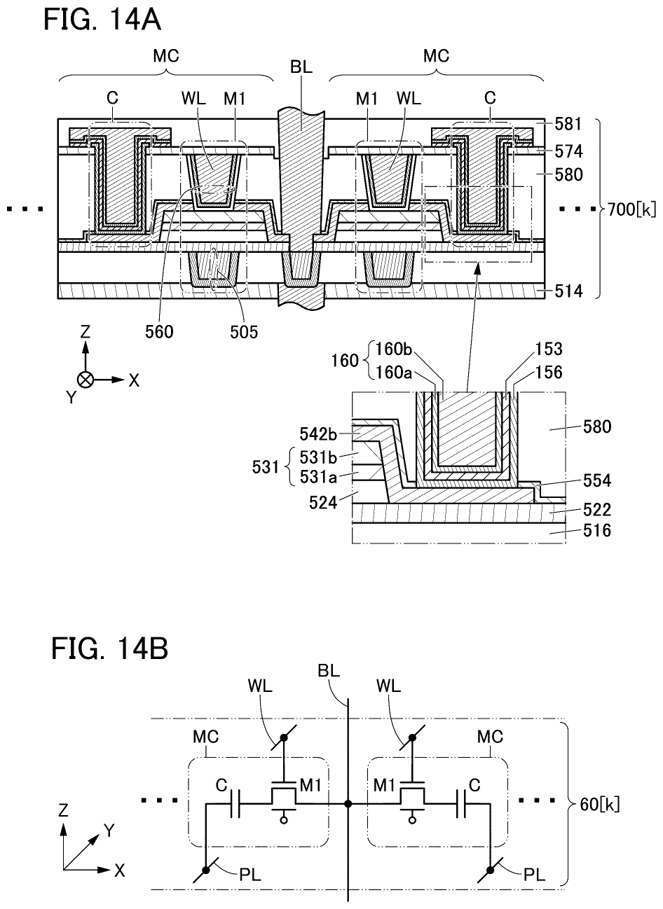

FIG. 14A illustrates a cross-sectional structure example of the memory layer 700[k]. In addition, FIG. 14B illustrates an equivalent circuit diagram of FIG. 14A. FIG. 14A illustrates an example where two memory cells MC are electrically connected to one bit line BL.

The memory cells MC illustrated in FIG. 13 and FIG. 14A each include the transistor M1 and a capacitor C. For example, the transistor 500 illustrated in the above embodiment can be used as the transistor M1.

Note that in this embodiment, a modification example of the transistor 500 is illustrated as the transistor M1. Specifically, the transistor M1 differs from the transistor 500 in that the conductor 542a and the conductor 542b extend beyond an edge of a metal oxide 531.

In addition, the memory cells MC illustrated in FIG. 13 and FIG. 14A each include a conductor 156 that functions as one terminal of the capacitor C, an insulator 153 that functions as a dielectric, and a conductor 160 (a conductor 160a and a conductor 160b) that functions as the other terminal of the capacitor C. The conductor 156 is electrically connected to part of the conductor 542b. Furthermore, the conductor 160 is electrically connected to a wiring PL (not illustrated in FIG. 14A).

The capacitor C is formed in an opening portion that is provided by removal of part of the insulator 574, the insulator 580, and an insulator 554. Since the conductor 156, the insulator 580, and the insulator 554 are formed along a side surface of the opening portion, the conductor 156, the insulator 580, and the insulator 554 are preferably deposited by an ALD method, a CVD method, or the like.

In addition, a conductor that can be used as a conductor 505 or the conductor 560 is used for each of the conductor 156 and the conductor 160. For example, titanium nitride formed by an ALD method is used for the conductor 156. Furthermore, titanium nitride formed by an ALD method is used for the conductor 160a, and tungsten formed by a CVD method is used for the conductor 160b. Note that in the case where the adhesion of tungsten to the insulator 153 is sufficiently high, a single-layer film of tungsten formed by a CVD method may be used for the conductor 160.

An insulator of a high permittivity (high-k) material (a material with high relative permittivity) is preferably used for the insulator 153. As the insulator of a high permittivity material, an oxide, an oxynitride, a nitride oxide, or a nitride containing one or more kinds of metal element selected from aluminum, hafnium, zirconium, gallium, and the like can be used, for example. In addition, the oxide, the oxynitride, the nitride oxide, or the nitride may contain silicon. Furthermore, insulating layers each formed of the above material can be stacked to be used.

As the insulator of a high permittivity material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high permittivity material allows the insulator 153 to be thick enough to inhibit leakage current and can ensure sufficient capacitance of the capacitor C.

In addition, it is preferable to use stacked insulating layers each formed of the above materials. A stacked structure using a high permittivity material and a material having higher dielectric strength than the high permittivity material is preferably used. An insulating film in which zirconium oxide, aluminum oxide, and zirconium oxide are stacked in this order can be used for the insulator 153, for example. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used. The use of stacked insulators with comparatively high dielectric strength, such as aluminum oxide, can improve the dielectric strength and can inhibit electrostatic breakdown of the capacitor C.

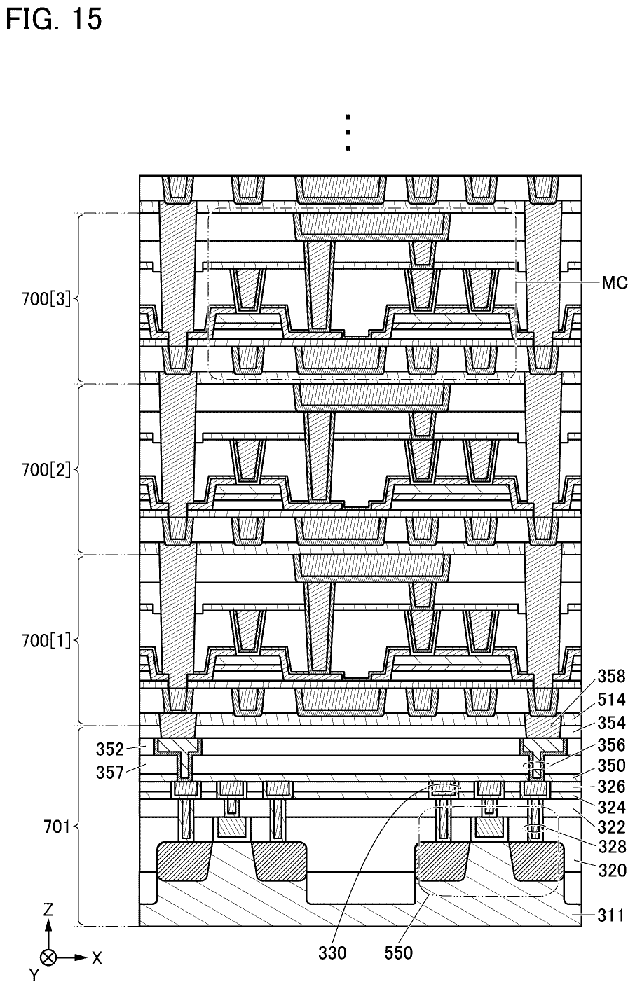

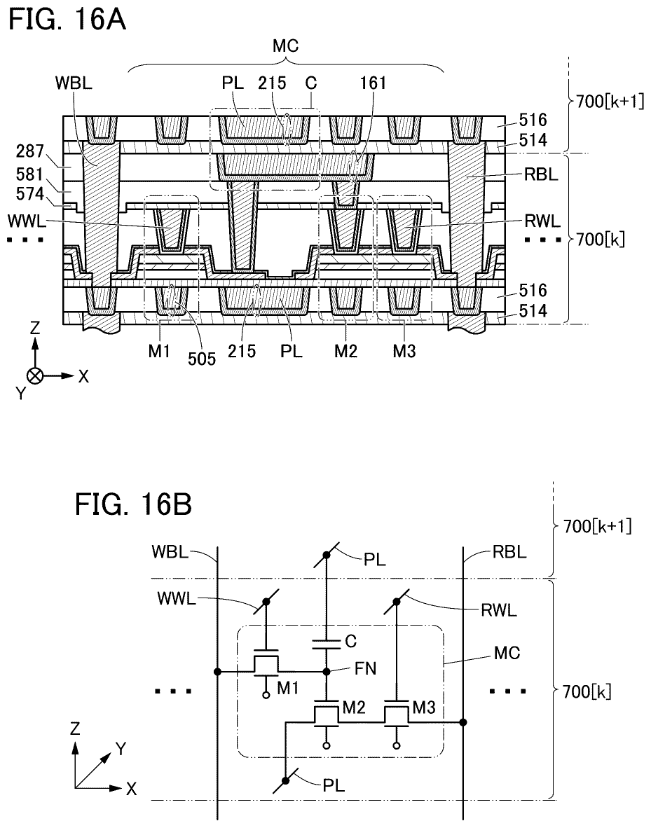

FIG. 15 illustrates a cross-sectional structure example of the case of using a NOSRAM memory cell circuit structure. Note that FIG. 15 is also a modification example of FIG. 13. In addition, FIG. 16A illustrates a cross-sectional structure example of the memory layer 700[k]. Furthermore, FIG. 16B illustrates an equivalent circuit diagram of FIG. 16A.

The memory cells MC illustrated in FIG. 15 and FIG. 16A each include the transistor M1, a transistor M2, and a transistor M3 over the insulator 514. In addition, a conductor 215 is provided over the insulator 514. The conductor 215 can be formed using the same material in the same process as those of the conductor 505 at the same time.

In addition, the transistor M2 and the transistor M3 illustrated in FIG. 15 and FIG. 16A share one island-shaped metal oxide 531. In other words, part of the one island-shaped metal oxide 531 functions as a channel formation region of the transistor M2, and another part thereof functions as a channel formation region of the transistor M3. Furthermore, a source of the transistor M2 and a drain of the transistor M3 are shared, or a drain of the transistor M2 and a source of the transistor M3 are shared. Thus, the area occupied by the transistor M2 and the transistor M3 is smaller than that of the case where the transistor M2 and the transistor M3 are independently provided.

In addition, in each of the memory cells MC illustrated in FIG. 15 and FIG. 16A, an insulator 287 is provided over the insulator 581, and a conductor 161 is embedded in the insulator 287. Furthermore, the insulator 514 of the memory layer 700[k+1] is provided over the insulator 287 and the conductor 161.

In FIG. 15 and FIG. 16A, the conductor 215 of the memory layer 700[k+1] functions as one terminal of the capacitor C, the insulator 514 of the memory layer 700[k+1] functions as a dielectric of the capacitor C, and the conductor 161 functions as the other terminal of the capacitor C. Furthermore, the other of a source and a drain of the transistor M1 is electrically connected to the conductor 161 through a contact plug, and a gate of the transistor M2 is electrically connected to the conductor 161 through another contact plug.

This embodiment can be implemented in combination with the other embodiments described in this specification as appropriate.

### Embodiment 5

In this embodiment, a transistor including an oxide semiconductor in a channel formation regions (an OS transistor) is described. Note that comparison of an OS transistor with a transistor including silicon in a channel formation region (also referred to as a Si transistor) is briefly described.

### [Os Transistor]

An oxide semiconductor having a low carrier concentration is preferably used for an OS transistor. For example, the carrier concentration in an oxide semiconductor in a channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Furthermore, electric charge captured by the trap states in the oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to stabilize electrical characteristics of the transistor, reducing the impurity concentration in the oxide semiconductor is effective. In addition, in order to reduce the impurity concentration in the oxide semiconductor, it is preferable that the impurity concentration in an adjacent film be also reduced. Examples of impurities include hydrogen and nitrogen. Note that impurities in an oxide semiconductor refer to, for example, elements other than main components of the oxide semiconductor. For example, an element having a concentration lower than 0.1 atomic % can be regarded as an impurity.

In addition, the OS transistor is likely to change its electrical characteristics when impurities and oxygen vacancies exist in the channel formation region in the oxide semiconductor, which might worsen reliability. In some cases, the OS transistor has a defect that is an oxygen vacancy in the oxide semiconductor into which hydrogen enters (hereinafter sometimes referred to as VoH), which generates an electron serving as a carrier. Furthermore, formation of VoH in the channel formation region might increase the donor concentration in the channel formation region. An increase in the donor concentration in the channel formation region might lead to a variation in threshold voltage. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Therefore, impurities, oxygen vacancies, and VoH are preferably reduced as much as possible in the channel formation region in the oxide semiconductor.

Furthermore, the bandgap of the oxide semiconductor is preferably wider than the bandgap of silicon (typically 1.1 eV), further preferably wider than or equal to 2 eV, still further preferably wider than or equal to 2.5 eV, yet still further preferably wider than or equal to 3.0 eV. With the use of an oxide semiconductor having a wider bandgap than silicon, the off-state current (also referred to as Ioff) of the transistor can be reduced.

Moreover, in a Si transistor, a short-channel effect (also referred to as an SCE) appears as miniaturization of the transistor proceeds. Thus, it is difficult to miniaturize the Si transistor. One factor in causing the short-channel effect is a narrow bandgap of silicon. In contrast, the OS transistor uses an oxide semiconductor that is a semiconductor material having a wide bandgap, and thus can suppress the short-channel effect. In other words, the OS transistor is a transistor where the short-channel effect does not appear or hardly appears.

Note that the short-channel effect refers to degradation of electrical characteristics that becomes obvious along with miniaturization of a transistor (a decrease in channel length). Specific examples of the short-channel effect include a decrease in threshold voltage, an increase in a subthreshold swing value (sometimes referred to as an S value or S.S.), and an increase in leakage current. Here, the S value refers to the amount of change in gate voltage which makes drain current change by one digit in a subthreshold region at constant drain voltage.

In addition, characteristic length is widely used as an indicator of resistance to a short-channel effect. The characteristic length is an indicator of the curvature of a potential in a channel formation region. The smaller the characteristic length is, the more steeply the potential rises, which means that smaller characteristic length has higher resistance to the short-channel effect.

The OS transistor is an accumulation-type transistor, and the Si transistor is an inversion-type transistor. Thus, the OS transistor has shorter characteristic length between a source region and the channel formation region and shorter characteristic length between a drain region and the channel formation region than the Si transistor. Accordingly, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor with the above structure can have favorable electrical characteristics even when a semiconductor device is miniaturized or highly integrated. For example, the OS transistor can have favorable electrical characteristics even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, the OS transistor can be more suitably used as a short-channel transistor than the Si transistor. Note that the gate length refers to the length of a gate electrode in a direction in which carriers move inside a channel formation region during operation of a transistor, which corresponds to the width of a bottom surface of the gate electrode in a plan view of the transistor.

In addition, miniaturization of the OS transistor can improve the high-frequency characteristics of the transistor. Specifically, the cutoff frequency of the transistor can be improved. When the gate length of the OS transistor is within any of the above ranges, the cutoff frequency of the transistor can be made higher than or equal to 50 GHz, preferably higher than or equal to 100 GHz, further preferably higher than or equal to 150 GHz in a room temperature environment, for example.

As described above, the OS transistor has advantageous effects such as low off-state current and capability of being manufactured with short channel length compared to the Si transistor.

The configuration, structure, method, and the like described in this embodiment can be used in combination as appropriate with the configurations, structures, methods, and the like described in the other embodiments and the like.

### Embodiment 6

This embodiment describes an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device according to one embodiment of the present invention are effective in achieving high performance, e.g., reducing power consumption.

### [Electronic Component]

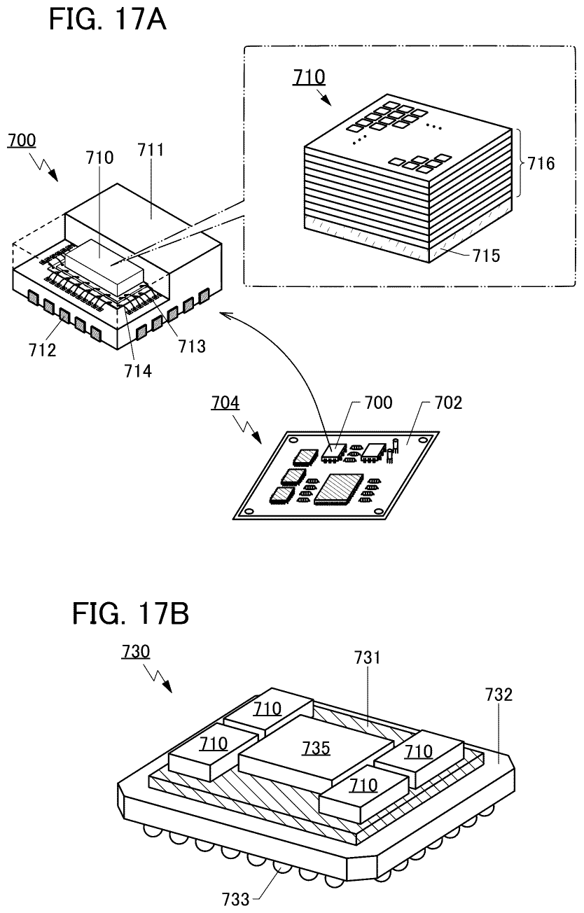

FIG. 17A illustrates a perspective view of a substrate (a mount board 704) on which an electronic component 700 is mounted. The electronic component 700 illustrated in FIG. 17A includes a semiconductor device 710 in a mold 711. FIG. 17A omits illustrations of some parts to show the inside of the electronic component 700. The electronic component 700 includes lands 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mount board 704 is completed.

In addition, the semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

In addition, with the on-chip memory structure, the size of a connection wiring and the like can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

Furthermore, it is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

Moreover, the semiconductor device 710 may be called a die. Note that in this specification and the like, a die refers to a chip piece obtained by, for example, forming a circuit pattern on a disc-like substrate (also referred to as a wafer) or the like and cutting the substrate into dies in a process of manufacturing a semiconductor chip. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 17B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. In addition, the semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate.” Furthermore, a through electrode is provided in the interposer 731 and the through electrode is used to electrically connect an integrated circuit and the package substrate 732 in some cases. Moreover, in a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving wide memory bandwidth. For this reason, the monolithic stacked-layer structure using the OS transistors is suitable. A composite structure where memory cell arrays stacked using a TSV and monolithically stacked memory cell arrays are combined may be employed.

In addition, a heat sink (a radiator plate) may be provided to overlap the electronic component 730. In the case where a heat sink is provided, the heights of integrated circuits provided on the interposer 731 are preferably aligned with each other. For example, in the electronic component 730 described in this embodiment, the heights of the semiconductor devices 710 and the semiconductor device 735 are preferably aligned with each other.

Electrodes 733 may be provided on a bottom portion of the package substrate 732 to mount the electronic component 730 on another substrate. FIG. 17B illustrates an example where the electrodes 733 are formed of solder balls. When the solder balls are provided in a matrix on the bottom portion of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

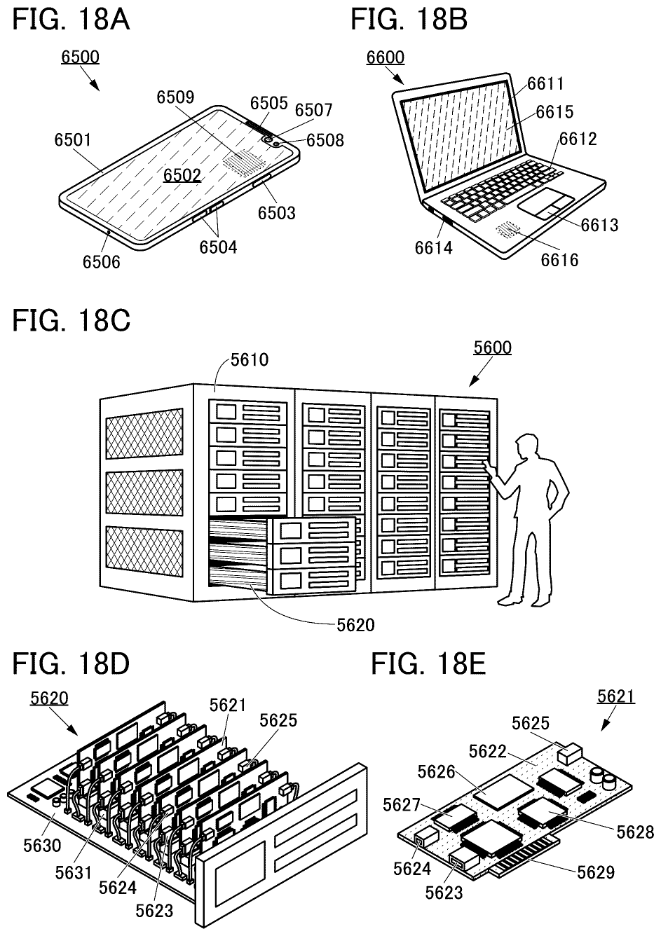

Next, FIG. 18A illustrates a perspective view of an electronic device 6500. The electronic device 6500 illustrated in FIG. 18A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device according to one embodiment of the present invention can be employed for the display portion 6502, the control device 6509, or the like.

An electronic device 6600 illustrated in FIG. 18B is an information terminal that can be used for a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The semiconductor device according to one embodiment of the present invention can be employed for the control device 6509, the control device 6616, or the like. Note that the semiconductor device according to one embodiment of the present invention is suitably used for each of the control device 6509 and the control device 6616 because power consumption can be reduced.

### [Large Computer]

Next, FIG. 18C illustrates a perspective view of a large computer 5600. In the large computer 5600 illustrated in FIG. 18C, a plurality of rack mount computers 5620 are stored in a rack 5610. Note that the large computer 5600 may also be referred to as a supercomputer.

The computer 5620 can have a structure in a perspective view illustrated in FIG. 18D, for example. In FIG. 18D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 18E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 18E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can each serve as, for example, an interface for performing power supply, signal input, or the like to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected.

The semiconductor device 5627 includes a plurality of terminals, and when the terminals are reflow-soldered, for example, to wirings of the board 5622, the semiconductor device 5627 and the board 5622 can be electrically connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be electrically connected. An example of the semiconductor device 5628 is a memory device. The electronic component 700 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device according to one embodiment of the present invention can be suitably used for space equipment such as equipment that processes and stores information.

The semiconductor device according to one embodiment of the present invention can include an OS transistor. A change in electrical characteristics of the OS transistor due to exposure to radiation is small. That is, the OS transistor is highly resistant to radiation and thus can be suitably used even in an environment where radiation can enter. For example, the OS transistor can be suitably used in the case of being used in outer space.

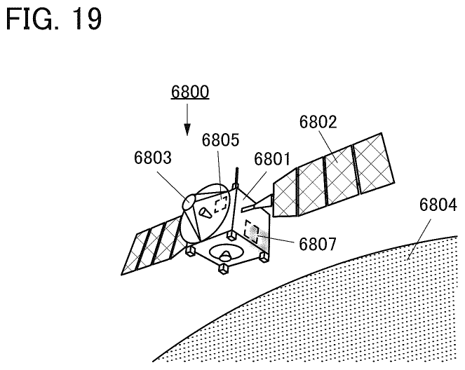

FIG. 19 illustrates an artificial satellite 6800 as an example of space equipment. The artificial satellite 6800 includes a body 6801, solar panels 6802, an antenna 6803, a secondary battery 6805, and a control device 6807. Note that FIG. 19 illustrates a planet 6804 in outer space, for example. Note that outer space refers to, for example, space at an altitude greater than or equal to 100 km, and outer space described in this specification may include the thermosphere, the mesosphere, and the stratosphere.

In addition, although not illustrated in FIG. 19, a battery management system (also referred to as a BMS) or a battery control circuit may be provided in the secondary battery 6805. An OS transistor is suitably used in the battery management system or the battery control circuit because low power consumption and high reliability even in outer space are achieved.

Furthermore, the amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

In addition, the control device 6807 has a function of controlling the artificial satellite 6800. The control device 6807 is formed using one or more selected from a CPU, a GPU, and a memory device, for example. Note that the semiconductor device according to one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

Alternatively, the artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is illustrated as an example of space equipment in this embodiment, the present invention is not limited thereto. The semiconductor device according to one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### [Data Center]

The semiconductor device according to one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device according to one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

In addition, since the semiconductor device according to one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device according to one embodiment of the present invention can achieve a data center that stably operates even in a high-temperature environment. Thus, the reliability of the data center can be increased.

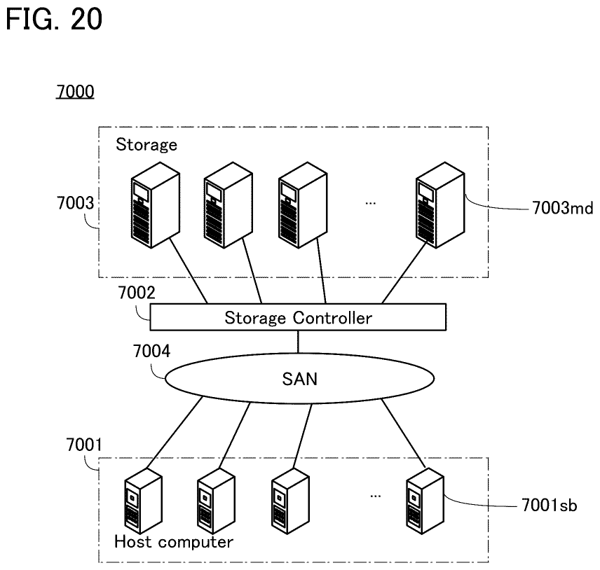

FIG. 20 illustrates a storage system applicable to a data center. A storage system 7000 illustrated in FIG. 20 includes a plurality of servers 7001sb as a host 7001 (indicated as “Host Computer” in the diagram). In addition, the storage system 7000 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device according to one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device according to one embodiment of the present invention. Furthermore, the semiconductor device according to one embodiment of the present invention has low power consumption and thus is effective as a global warming countermeasure.

The composition, structure, method, and the like described in this embodiment can be used in combination as appropriate with the compositions, structures, methods, and the like described in the other embodiments and the like.

### Supplementary Notes on the Description in this Specification and the Like

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not necessarily limited to the illustrated scale. Note that the drawings are schematically shown for clarity, and embodiments of the present invention are not limited to shapes, values or the like shown in the drawings. For example, variation in signal, voltage, or current due to noise, variation in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

### REFERENCE NUMERALS

10: semiconductor device, 20: element layer, 21: control portion, 22: arithmetic portion, 24: memory portion, 30: element layer, 31: cache memory, 32: input/output portion, 33: memory portion, and 34: memory cell.

1. A semiconductor device comprising:
a first element layer comprising a control portion; and
a second element layer stacked and provided over the first element layer,
wherein the second element layer comprises a memory portion configured to function as a set associative type cache memory comprising n ways and an input/output portion configured to input/output data stored in the memory portion, and wherein n is greater than or equal to 2,
wherein in the second element layer, n element layers are stacked and provided,
wherein the n element layers each comprise a first transistor,
wherein in the first transistor, a semiconductor layer comprising a channel formation region comprises silicon,
wherein the n element layers each comprise the memory portion and the input/output portion separately provided, and
wherein the memory portion provided in any one of the n element layers outputs data corresponding to any one of the n ways to the control portion through the input/output portion provided in any one of the n element layers.

2. The semiconductor device according to claim 1, wherein a memory cell included in the memory portion is an SRAM cell.

3. The semiconductor device according to claim 1,
wherein the n element layers each comprise a through electrode provided to penetrate a substrate comprising the first transistor, and
wherein the through electrodes provided in the element layers are electrically connected through a metal bump provided between the different element layers.

4. The semiconductor device according to claim 1,
wherein the first element layer comprises an arithmetic portion, and
wherein the second element layer is provided in a region not overlapping a region where the arithmetic portion is provided.

5. The semiconductor device according to claim 1, wherein
the input/output portions included in the n element layers comprise a region where the input/output portions included in the n element layers overlap each other.

6. A semiconductor device comprising:
a first element layer comprising a control portion; and
a second element layer stacked and provided over the first element layer,
wherein the second element layer comprises a memory portion configured to function as a set associative type cache memory comprising n ways and an input/output portion configured to input/output data stored in the memory portion, and wherein n is greater than or equal to 2,
wherein in the second element layer, n element layers are stacked and provided,
wherein the n element layers each comprise a first transistor,
wherein in the first transistor, a semiconductor layer comprising a channel formation region comprises an oxide semiconductor,
wherein the n element layers each comprise the memory portion and the input/output portion separately provided, and
wherein the memory portion provided in any one of the n element layers outputs data corresponding to any one of the n ways to the control portion through the input/output portion provided in any one of the n element layers.

7. The semiconductor device according to claim 6, wherein a memory cell included in the memory portion is a memory cell comprising the first transistor.

8. The semiconductor device according to claim 6,
wherein the n element layers are provided by superimposing a plurality of layers each including the first transistor, and
wherein the n element layers are electrically connected through a wiring layer provided in the layer including the first transistor.

9. The semiconductor device according to claim 6,
wherein the first element layer comprises an arithmetic portion, and
wherein the second element layer is provided in a region not overlapping a region where the arithmetic portion is provided.

10. The semiconductor device according to claim 6, wherein the input/output portions included in the n element layers comprise a region where the input/output portions included in the n element layers overlap each other.

11. The semiconductor device according to claim 6, wherein the oxide semiconductor comprises In, Ga, and Zn.
